(19) United States
(12) Patent Application Publication
(10) Pub. No.: US 2024/0243691 A1
(43) Pub. Date: Jul. 18, 2024

(54) Solar Panel Ground Anchoring System

(71) Applicant: Stella Power Inc., Calgary, Alberta (CA)

(72) Inventors: Kenneth Eugene Lebioda, Calgary, Alberta (CA); John Charles Goetz, Calgary, Alberta (CA); Christian Bennett Lebioda, Calgary, Alberta T2P 0L6 (CA); Nolan Kenneth Lebioda, Calgary, Alberta (CA); Christopher Ross Armstrong Halliday, Calgary, Alberta (CA); Keith Palmer, Calgary, Alberta (CA); Connell Hunka, Calgary, Alberta (CA); Shannon McBennett, Calgary, Alberta (CA)

(21) Appl. No.: 18/562,184

(22) PCT Filed: May 17, 2022
(86) PCT No.: PCT/CA2022/050776

§ 371 Date: Nov. 17, 2023

Related U.S. Application Data
(60) Provisional application No. 63/189,364, filed on May 17, 2021.

(51) Int. Cl. H02S 20/10; E02D 27/50

(52) U.S. Cl. CPC H02S 20/10; E02D 27/50

(57) ABSTRACT

Devices for anchoring one or more solar panels are described. The devices include a container configured to receive ballast material to provide increased mass for anchoring one or more solar panels to a ground surface. The container also includes a solar panel connection system for securing one or more solar panels to the container and may support various additional features providing enhanced stability and protection of other solar array components. The devices may be used in combination with other solar panel support structures to create extended solar panel assemblies which may include additional energy collection features.

### FIELD

Devices for anchoring one or more solar panels are described. The devices include a container configured to receive ballast material to provide increased mass for anchoring one or more solar panels to a ground surface. The container also includes a solar panel connection system for securing one or more solar panels to the container and may support various additional features providing enhanced stability and protection of other solar array components. The devices may be used in combination with other solar panel support structures to create extended solar panel assemblies which may include additional energy collection features.

### BACKGROUND

The pursuit of renewable energy, specifically in power applications, continues to grow rapidly in its scope and application globally. The use of solar arrays (e.g. solar panels and/or photovoltaic cells) to convert the radiant energy of sunlight into heat or electrical energy has increased in development and scope over the past several decades. However, to date, the majority of solar panel systems are arranged with conventional approaches and largely designed for permanent equator facing systems. Typical installations include horizontal mounting on residential roofs and building structures or in land-based array projects where arrays of solar panels are deployed in fields.

Although solar panel technologies have adopted different approaches to improve efficiency over the past few decades, and while the cost of solar energy is now competitive with other non-renewable approaches, there continues to be a need for improvements. In particular, there has been a need for improvements in efficiency of overall power output, balance of system cost inputs, and ease of servicing in residential, industrial, brownfield lands and other areas where earth moving is prohibited, as well other large land-array applications. Novel approaches that improve key factors in the collection of power such as reduced installation, improved environmental, social governance (ESG) metrics, maintenance costs, and protection from environmental forces such as wind damage are needed to make this type of sustainable power even more competitive in the growing global need for renewable and sustainable power sources.

One key area for improvement with legacy solar array applications is inefficient land use required for power generation.¹ It is known that large solar array applications require large land footprints as well as labor intensive assembly installation and servicing processes. Additional issues with these types of applications in residential and/or industrial rooftop installations include potential damage to structures over extended periods of time due to added loads both from weight and wind-loading forces. Importantly, whether a solar array is designed for a field/ground installation or a building installation, each installation will require significant engineering to design appropriate support structures for a specific installation. While standard support frames may be adaptable to different arrays and may permit a degree of flexibility to allow installation in a variety of different land/building locations, a degree of customization will likely be required for almost all installations due to particular features or characteristics of a specific location. For example, a field installation will require foundation structures specific to the field location where the depth/size of the foundation will require consideration to such factors as the slope of the ground, the soil/ground characteristics, wind loading on the arrays, as well as other considerations such as annual ground frost depth. Similarly, a building installation will also require consideration to the particulars of attaching a large and heavy array to a roof structure, the underlying support within the building as well as wind loading

Accordingly, there has been a need for solar panel systems that improve the solar panel density with increased stability.

### SUMMARY

According to one aspect, there is provided an anchoring system for anchoring at least one solar panel against the ground, the anchoring system including: a container configured to hold ballast within the container, the container having a lower surface for engagement with the ground and an upper surface having a solar panel connection system for attaching at least one solar panel to the container at an angle with respect to the ground.

In various embodiments:
the container is a hollow plastic container configured to hold water and/or a particulate as ballast.
the container includes at least one fill port for filling the container with the ballast material.
the container includes at least one drain port for draining the ballast material from the container.
the container has a container length, container width and container height and where the solar panel connection system is a groove formed in the upper surface of the container extending along the container length and where the groove is configured to receive and secure an edge of at least one solar panel to the container.
the container has a container length, container width and container height and where the solar panel connection system is at least one bracket configured to the upper surface and each at least one bracket is configured to connect an edge of the at least one solar panel to the at least one bracket.
the solar panel connection system is configured to enable adjustment of a solar panel angle with respect to the ground when a solar panel is connected to the container
the container has a base surface and an upper surface and where the base surface is wider than the upper surface such that the container defines a substantially trapezoidal cross-section.
the base surface includes an upwardly-extending recess along the container length for receiving a lifting device within the recess.
the container further includes a cable groove extending along the container length configured to support at least one solar panel cable.
the container further includes a reflector support configured to support a reflector on the upper surface of the container.
the container is configured to connect at least one solar panel support bracket to the container and where the anchoring system further comprises a solar panel support bracket having a bracket upper surface configured to support a lower surface of a first solar panel a first angle with respect to the ground.
the solar panel support bracket further comprises an upper corner extension extending laterally from the solar panel support bracket, the upper corner extension configured to support a second panel at a second angle with respect to the ground.
the solar panel support bracket is plastic.
the container is configured with at least one recessed slot on a side surface of the container and wherein the solar panel support bracket has an edge configured to lock with the recessed slot.
the container is configured with an end connection system configured to connect to a corresponding end connection system of a second container enabling interconnection of multiple containers longitudinally.
the container includes a cross-member connection system configured to connect a cross-member between two or more corresponding containers laterally separated from one another.
the anchoring system includes a cross-member configured to connect to the cross-member connection system, the cross-member further configured to provide a fixed separation between adjacent rows of containers.
the cross-member is plastic.
the anchoring system includes at least one panel lift member configured to connect a container with a solar panel and to provide vertical separation between a solar panel and a container.
the anchoring system includes at least one torsion control member configured to connect a container with a solar panel and to provide torsional stability to an elevated solar panel.

In another aspect, a kit is described, the kit including at least two hollow containers configured to hold ballast material within the container, each container having a lower surface for engagement with the ground and an upper surface having a solar panel connection system for attaching at least one solar panel to each container at an angle with respect to the ground.

In various aspects:
The kit includes at least two solar panels.
The kit includes at least one panel support bracket having a bracket upper surface configured to support a lower surface of a first solar panel at a first angle with respect to the ground.
The kit includes at least one cross member configured to connect two containers together with a fixed separation between the two containers.
The kit includes at least one solar panel connector configured to connect two solar panels together.
The kit includes a reflector and wherein at least one container is configured to the reflector to the at least one container at an angle to the ground.

In another aspect, a solar panel assembly is described, the assembly including: at least two hollow containers configured to hold ballast material within the container, each container having a lower surface for engagement with the ground and an upper surface having a solar panel connection system for attaching at least one solar panel to each container at an angle with respect to the ground; a first solar panel connected to a first container; a second solar panel connected to a second container; wherein the first and second solar panels are connected together to define a solar panel assembly wherein each solar panel is angled with respect to the ground.

In various aspects:
the solar panel assembly includes at least one panel support bracket connected to the first container and having a bracket upper surface configured to support a lower surface of the first solar panel at a first angle with respect to the ground.
the solar panel assembly includes at least one cross member connected to the first container and second container.
the solar panel assembly includes at least one solar panel connector commonly connected to the first and second solar panels.
the solar panel assembly includes a reflector connected to the first container at an angle to the ground.
the solar panel assembly includes a third solar panel and wherein the first and second solar panels are connected to one another by the third solar panel between the first and second solar panels.
each container is filled with water and the solar panel assembly further includes a pump and dispenser in fluid communication with container water.
the solar panel assembly includes a rain harvesting vessel or screen configured to convey captured precipitation into the first container.

### BRIEF DESCRIPTION OF THE DRAWINGS

The invention is described with reference to the drawings in which:

FIG. 1 is a side view illustration of one embodiment of a 2-panel system 10.

FIG. 2 is a side view illustration of another embodiment of an asymmetric 3-panel assembly 20.

FIG. 3A is a perspective view of the assembly 20 of FIG. 2.

FIG. 3B is an array of extended assemblies formed of assembly units 20.

FIG. 4 is a side view illustration of the assembly 20 of FIGS. 2 and 3 indicating the presence of generic perimeter weighting components 28.

FIG. 5 is a side view illustration of the assembly 20 which is supported by an embodiment of a ballast support apparatus 30 which includes a pair of ballast containers 100.

FIG. 6 is an end elevation view of a first embodiment of a ballast container 100 indicating placement of a panel into a groove 107 in the ballast container 100.

FIG. 7 is an end elevation view of a second embodiment of a ballast container 200 indicating placement of a panel into a groove 207 in the ballast container 200.

FIG. 8 is a partial perspective view of the ballast container 100 of FIG. 6.

FIG. 9 is a partial perspective view of another embodiment of a ballast container 300 having a radiused channel 309 retaining a rotatable bracket 306.

FIG. 10 is an exploded partial perspective view indicating placement of the rotatable bracket 309 in the radiused channel.

FIG. 11 is a top view of a series of connected assemblies including polar facing panels PFP, top panels TP, equator facing panels EFP corner panels CP and side panels SP all supported by ballast containers 100, 180 and 190.

FIG. 12 is an end view of another embodiment of a ballast container 400 provided with a hinged reflector 428 and cable trough 424.

FIG. 13 is an end view of another embodiment of a ballast container 500 provided with a hinged reflector 528 coupled to a ratchet hinge 523.

FIG. 14A is an end view of another embodiment of a ballast container 600 provided with a hinged reflector 628 which is configured to cover a fill port 602 and a cable trough 624 showing the reflector 628 in the closed position.

FIG. 14B is the same view of the same embodiment of the ballast container 600 of FIG. 14A showing the reflector 628 in the open position and indicating reflection of irradiation from the reflector 628 to the panel.

FIG. 15 is a top partial view of an assembly including a polar facing panel PFP, top panels TP, an equator facing panel EFP supported by ballast containers 400 indicating electrical lines extending from the panels PFP, TP, EFP to three corresponding cables contained in a cable trough 424 formed in the ballast container 400.

FIG. 16 is a side elevation view of an assembly which includes ballast container 400 and associated reflector 428.

FIG. 17 is an end view of another embodiment of an assembly 30 which includes an alternative support arrangement.

FIG. 18A is a side elevation view of a support structure 901.

FIG. 18B is a top view of support structure 901.

FIG. 19 is a top view illustrating a series of three support structures 901 being connected to another embodiment of a ballast container 1000.

FIG. 20 is a top view of an assembly frame 60 formed from opposed ballast containers 1100, support structures 901 and 911 and cross members 920.

FIG. 21A is a side elevation view of another embodiment of a support structure 1301.

FIG. 21B is a top view of support structure 1301.

FIG. 22A is an end elevation view of another assembly embodiment 70 including a ballast container 1200 with three connected support structures 1301 retaining two sub-reflectors 1310 and a bi-facial photovoltaic panel BFP.

FIG. 22B is another end elevation view of a different arrangement of assembly embodiment 70 including a ballast container 1200 with three connected support structures 1301 retaining two sub-reflectors 1310 and a bi-facial photovoltaic panel BFP.

FIG. 23 is a top view of a portion of an assembly frame 80 showing two adjacent ballast containers 1400 which have half sockets 1450 at their ends for receiving a plug end 1403 of a support 1401.

FIG. 24A is a perspective view of an embodiment of a photovoltaic frame 1530 which includes features for series or parallel wiring of photovoltaic panels.

FIG. 24B is a magnified view of the access port 1531 and closure 1532 of the photovoltaic frame 1530 of FIG. 24A.

FIG. 25 illustrates series wiring of power lines of three photovoltaic panels with power lines passing through access ports 1531.

FIG. 26 is a top view of an assembly embodiment which incorporates photovoltaic panels PFP, TP and EFP which are provided with access ports 1531 used in parallel wiring.

FIG. 27 is a top view of an assembly embodiment which incorporates photovoltaic panels PFP, TP and EFP which are provided with access ports 1531 used in series wiring.

FIG. 28 is a transparent side elevation view of a photovoltaic frame 1630 which includes an access port 1631 for series or parallel wiring, an internal reflector 1637 and a bifacial panel with upper and lower PV cell layers 1638 and 1639.

FIG. 29 is a side elevation view of another embodiment of a ballast container 1700 which supports a pump 1761 and a rain harvesting vessel 1771.

FIG. 30 is a side elevation view of another embodiment of a ballast container 2000 which includes an upper rain collector screen 2017.

FIG. 31 is a side elevation view of another embodiment of a ballast container 1800 which includes a convex reflector 1828.

FIG. 32 is a top view of a part of an array formed using ballast containers 1800.

FIG. 33 is a side elevation view of another assembly 90 which includes a brace member 1901 and brackets 1902 and 1903.

FIG. 34 is a side elevation view of another embodiment of an assembly 2200 with ballast containers 2100 and support structures 2101.

FIG. 35 is a front elevation view of the assembly 2200 of FIG. 34.

### DETAILED DESCRIPTION

### Introduction and Rationale

The pursuit for greater efficiency in renewable energy projects utilizing solar energy remains unabated. An increasing part of capital requirements for these energy projects is construction of support systems such as racks to support solar array systems and land preparation costs deployment of the support systems.

As described herein, solar arrays generally refer to solar energy systems that are comprised of multiple similar or substantially similar units of a solar energy collection system that individually can harvest solar energy. Such units are typically arranged in multiple side-by-side rows and/or a pattern to form an array. Each unit of a solar energy collection system may be comprised of and/or assembled from one or more solar panels. Solar panels may be supported in perimeter frames and may be connected together via the frames or multiple solar panels may be assembled within a common frame. Solar panels may be generally flat and rigid rectangular panels; however, flexible panels are also known. Solar panels may be photovoltaic panels that are used to generate electricity and solar heating panels used to heat water or other thermal liquids. In the context of this description, the systems and methods described herein generally relate to solar energy systems used to generate electricity through the use of photovoltaics; however, the systems and methods described herein may also be used in conjunction with solar heating of thermal fluids.

To this end much of existing solar array development projects still utilize ground mounted racking systems that use metal-frame based component systems coupled to ground mounted systems including concrete foundations. In many cases, concrete foundations require below grade installation in areas that have typical winter temperatures below zero degrees Celsius. Detailed engineering is also typically required to determine wind load requirements for the solar array systems as the systems are exposed to shear, torsion and uplift forces from wind.

Although solar array systems have adopted different approaches to improve impact from wind, the anchoring and racking systems used over the past few decades, which are still deployed in many micro grid and large utility array systems utilizing fixed arrays installed at a variety of angles depending on latitude (between 10-35 degrees), are vulnerable to significant uplift forces of wind.² Moreover, the American Society of Civil Engineers has articulated this issue of wind load regarding the proper evaluation and attachment methods that will ensure that photovoltaic systems such as fixed and or single axis arrays can withstand windstorm events. The American Society of Civil Engineers has specific codes to deal with this issue. However, it has been reported that these documents and recommendations still do not provide adequate guidance to the design professionals and code officials tasked with assessing wind forces on photovoltaic installations.³ This lack of guidance and detailed specifications creates ongoing obstacles for advancements on this issue in the photovoltaic industry. The resulting problems can include frustrated installers, instability in future investments and wind-related structural failures. In addition, uncertainty about what constitutes a safe and secure installation for a given wind load can slow or even stop the approval process for solar installations and complicates the training of code officials. Improving array designs and anchoring systems that minimize wind loads on solar arrays requires new approaches for this problem.

Weather events such as windstorms remain as the most common causes of failure of solar installations. Steps have been taken in the United States to catch up with other industries towards a dedicated chapter for photovoltaic array racking and anchoring systems within the American Society of Civil Engineers code. Improvements in design of fixed and single axis solar systems with novel array designs and systems would address these ongoing issues.

The inventors have recognized that solar panel assembly systems are needed with improvements in efficiency to address wind effects, which are produced from sustainable materials, and which have improvements in the balance of system cost inputs along with the ease and servicing of maintaining large solar array systems such as large industrial photovoltaic array applications.

Legacy photovoltaic array systems have numerous issues relating to their racking and support structures, which need to be addressed to ensure solid integrity specially to deal with wind loads and violent windstorms. Some large solar array installations can be exposed to severe weather with wind gusts of up to 200 miles per hour, for example during a hurricane on the eastern seaboard of the US. Therefore, calculating wind load is an important factor to consider.⁴ Moreover, reports of multiple dual-axis solar array projects failing as a results of wind forces have also been reported in certain regions of Europe such as in Spain. As a result, the industry has provided some solution to this problem, one being horizontal trackers. This solution provides improved energy gain and less racking and steel product required compared to a dual-axis tracker system. However, systems incorporating horizontal trackers are not without issues. For example, horizontal tracking systems are limited by the range of angle that the array can be shifted for optimal energy output and the shadow impact of subsequent rows that are placed behind the initial array row. Importantly, this type of racking system, will often require below ground excavation and use of cement foundations, which comes at a considerable cost to the overall solar array system installation and continued operations. In many current large utility solar array development projects, below ground mounted support material such as concrete foundations, screw piles and/or metal poles are used.

As noted, there are certain limitations with this type of racking system such as installation expense, reclamation costs of these projects and the ongoing use of material that may be perceived as non-sustainable.

Further, below-ground foundations required for traditional solar panel arrays that are designed to withstand wind-loading requirements may also be required to be below the frost line in order to prevent movement of the above ground panel structures due to frost heaving As can be appreciated, foundations, including footings, concrete pads, concreted columns, piles etc. that meet local codes can substantially add to the cost of an installation as such foundations may have to be at least 4 feet deep in the ground.

However, to the extent that wind-loading requirements can be reduced by various design, it may not be possible or desirable to reduce the depth of foundations given the potential for a panel system to shift or move, again as a result of frost-heaving at various times of the year without damaging the solar panel system. Thus, to the extent that foundation mass/depth can be reduced due to reduced wind-loading there is also a need for foundation systems and support systems that enable a degree of movement of both the foundations and panel systems without damaging the solar panels.

As a result of these issues, a novel approach to current array design limitations is presented below.

The approaches, as described herein, recognizes that supports for arrays of solar panels could be provided by generally hollow enclosed containers holding water or other flowable materials of similar density as ballast material(s) and having features configured for supporting the solar panels. Such ballast containers form the basis of a support apparatus for solar panels which is intended to be marketed as a “floating advanced perimeter ballast (FAB) system. As used herein, the term “floating” is used to convey the meaning that the ballast vessels are not required to be attached to the ground, such as by stakes or below-grade structures such as foundations in the normal sense. That is, floating is meant to convey that the FAB system lies on the ground surface in a manner that enables the FAB system to be positioned and/or removed without requiring significant ground excavation and where the majority of the mass of the FAB system is substantially at a ground surface level. However, in some installations and in some embodiments, certain parts of the FAB system may be attached to below ground anchors without departing from the general meaning of the term floating. In addition, while under certain conditions, the systems as described herein may be placed on a ground surface without any surface preparation, many installations may require, or it would be desirable to conduct some surface preparation. For example, ground levelling may be desired to ensure that each unit of an installed solar array and the entire array are generally uniform within a given land area. In addition, it may be desired to enhance drainage around individual units of an array or the entire array to promote drainage away from units, for example to prevent ground water pooling and/or minimize frost heave. Such preparation may include installation of drainage channels, piping and the like and/or laying down gravel and other materials to assist drainage. Further, in some applications, minimal use of ground screws and/or metal bars may be utilized if appropriate to some installations.

Using water as ballast material is advantageous because it is dense, abundantly available (for example, non-potable water may be used), less expensive, and because draining of the vessels to allow the water ballast to be absorbed into the soil is convenient in situations where significant repositioning or adjustment of a deployed photovoltaic array may be required. In other embodiments, other materials with different density may be used as ballast either alone or in combination with water ballast, such as sand, gravel or dirt, for example. In some installations, ballast may also be concrete or a combination of any of the above materials.

By having the entire system and its components “floating” on land (i.e. not anchored into the ground by conventional means), expensive below grade foundation systems are not required and thus will most likely improve overall economics. Less ground preparation is required and large solar arrays can be conveniently removed from the site by either emptying the ballast material from the vessels and/or using heavy equipment such as bulldozers or backhoes to lift/push the FAB systems without deeper land excavation.

In various embodiments, the system utilizes plastics such as polypropylene. Such plastics may be recyclable/recycled plastic materials. For example, incorporating recycled plastics into new photovoltaic array projects transfers these by-products away from inherent single use product applications to more sustainable legacy products that could last for several decades. FAB systems can thus provide a new use for petroleum-based by-products to be used in additional renewable energy projects, satisfying ESG initiatives and supporting efforts to develop a fully circular economy in support of initiatives such as the United Nations' Sustainable Development Goals (SDGs).

The technology described herein includes non-exhaustive examples of “floating” perimeter-based ballast assemblies for three-dimensional land-based micro-grid and large utility-based solar panel systems that would not require below ground concrete ballast anchoring and attachment structures for structural integrity. Such assemblies may be used, for example, in construction of a component of a three-dimensional array platform as described in U.S. Provisional Application No. 63/039,775.9

The assemblies described include ballast containers constructed of sequestered petrochemical and/or plastic (e.g. polypropylene) materials which enable functional attachment to solar panels in a specific manner. The inherent advantages include minimization of wind impact, and complete removal or substantial removal of a requirement for below ground foundations.

In addition, the FAB systems described can reduce land impact disturbance and future reclamation costs of such projects and increased use of sequestered petrochemical byproducts such as polypropylene and or low leaching petrochemicals such as high density polyethylene (HDPE) for a period of greater than 25 years. These potential dynamics offer a novel integrated anchoring system that allows lower racking and ground development capital expenditures for large solar array projects as well as convenient disassembly processes when a given installation requires replacement.

Micro-grid and large-scale utility solar arrays also require racking and internal support structures that also provide integral support and attachment for solar panels. These systems for the most part exclusively use metal and or aluminum structures that provide the support for panels while anchoring of such system usually is attached below ground by pole and or metal girding vertical supports that are tied to below ground concrete piles or anchoring screws, all of which penetrate the earth and leave below ground structures even after decommissioning of such projects.

Innovations in ground mount foundations and racking systems have lagged. There have been multiple evolutionary improvements in photovoltaics, inverters, batteries and other balance of system technologies. These improvements are key in driving costs down in large utility and microgrid solar array systems. The ballast container embodiments described herein allow for convenient attachment of photovoltaic panels and integration of wiring within the structure of the ballast container to provide protection from the weather elements. The proposed result of a photovoltaic assembly supported by a “floating” ballast container (FAB) system provides advantages such as rapid deployment, use and divergence of petrochemical by-products from single use applications to much longer sequestered products that are integral parts of the development and production of large renewable energy projects. There is little or no penetration of the soil, and only limited use of power equipment may be required to deploy such light-weight components. Additionally, integration of additional system components such as ballast reflectors can provide additional power output based on their ability to focus and target additional irradiance from the sun back to polar facing photovoltaic panels

The process of filling a ballast container is facilitated by provision of a filling port, preferably on an upper surface of the ballast container to allow rapid water filling to pre-specified markings on such ballast components that would allow for proper expansion of the water to ice when deployed in colder climate conditions. A given ballast container may be configured with sufficient interior volume to retain from about 500 to about 1000 pounds of water, for example, to provide a stable anchoring structure for a photovoltaic assembly. These novel and design differences of such components simplify the construction and deployments process of installation of large renewable energy projects.

When a solar panel assembly is in its final position, fully assembled, aligned and leveled, each ballast container rests upon the ground. Embodiments of the ballast container provide a base footprint sufficient to be supported by a variety of soil conditions. The ability to conduct simple, inexpensive field load tests to measure the actual (vs. calculated) holding strength of the ballast containers can reduce or eliminate the need for geotechnical reports and related inspections and can meet design specifications with minimal engineering.

In most cases, renewable energy projects, such as large-scale solar array projects, must plan for eventual movement and or decommissioning. The modular approach provided by the components described herein provides for a more modular system that can be disassembled for use at another location. Additional advantages are realized in projects that benefit from this “lift and shift” portability, such as providing temporary power during disaster recovery efforts. Further details on the specifics related to the decommissioning process articulate the need to remove foundations, steel piles, and electric cabling and conduit up to two feet (24 inches) below any soil surface.⁵ All of these processes and requirements add to the overall system cost. Any novel system components that could minimize and or remove these processes as part of a decommission process would provide accretive value to any investment to such a project.

Embodiments of the photovoltaic assemblies described herein can be mounted on the ground in various landscapes including a variety of soil types, sand, desert hard pan or limestone, over pavement or capped landfills, or in climates subject to freeze/thaw cycles given that the technology is compatible with such surfaces. The features of the assembly components overcome several problems that affect other types of ground mounted foundations.

In some deployments, FAB systems may move as a result of frost heave and, in some embodiments, the FAB and solar panel support assemblies are able to move without damaging panels.

The assemblies described herein performs similar functions of traditional racking and support systems used in today's solar array marketplace. By utilizing peripheral ballast containers using recyclable plastics and also by utilizing liquid/particulate ballast (e.g. water or sand), the FAB systems offer advantages over existing ballast and racking systems that require ground engineering to deploy concrete structures below ground to provide resistance to wind impact and structural integrity for photovoltaic panels.

The systems described include low-profile plastic-based ballast units that anchor and fit to the bottom of solar panels, all within a low profile aligned structure that has specific design features that enhance elongated rows of solar panels within a three dimensional structure that optimizes energy density, reduces land use, reduces impact of wind and improves economics of overall costs of such systems. The FABs include a range of shapes and sizes that are optimized to fit with photovoltaic panels at minimal installation cost at the same time as providing maximum structural integrity. This allows for more efficient panel installation and materially greater overall efficiencies in labor and engineering requirements for below ground ballast systems.

Some FAB and photovoltaic assembly embodiments include ballast containers with specific dimensions to provide specific masses of ballast which may be easily deployed by a single individual that offers a more efficient and safe use of ballast-based products that do not require large machinery to drill into the ground for ballast anchoring. The ballast containers may be easily filled with safe and cheap flowable ballast material via a portal system that allows for rapid filling and the ability for material to freeze and expand such as water and/or sand or dirt. Such ballast material is readily available and is generally low-cost.

In some embodiments, the ballast containers include a trough or housing for retaining electrical power transmission cabling to allow for easy access and servicing. It is envisioned that in most cases only one side of the perimeter of an assembly will require a ballast container with this feature, while other perimeter edges could employ simplified ballast containers. A strong and lightweight protective cover that may be integrated into the ballast container to protect the cables. Some embodiments may include individual sub-grooves or channels within the trough that would allow each panel (e.g. north, top, side and south panel) and associated panel wiring to easily connect to a major main collection wiring system that would direct energy down to other system components for the collection and regulation of energy captured by multiple photovoltaic assemblies.

In some embodiments, the ballast containers include one or more anchors for attachment to one end of support structures that are themselves attached at the opposite end to vertical support brackets between the solar panels. Preferably, the support structures are also made of sequestered petrochemical and/or plastic materials. More preferably, the support structures are hingedly attached to both the anchors and the vertical support brackets to allow for “play” between the ballast containers and the solar panels due to conditions including wind and snow. In these embodiments, the ballast containers on either side of the solar panels may be secured at a set position in relation to one another by a trestle tie linking one ballast container to its opposite partner.

Further advances in large solar array project deployments may include the use of bifacial photovoltaic panels. According to the recent 11th edition of the International Technology Roadmap for Photovoltaic Report,⁶ the forecasted market share for bifacial modules is expected to grow substantially within the next decade. Key drivers for the growth and adoption of these type of panels are the reported improved energy yields per module area of the bifacial modules, as compared to monofacial modules. Further, according to the above-referenced NREL study, bifacial modules that collect light on both sides of a panel while also following the sun throughout the day illustrate the benefit of using bifacial panels in obtaining more power production without expanding system footprints or significantly reconfiguring the panels. Early results from this study showed a significant boost from the bifacial panels of an up to 9% gain in energy production relative to monofacial modules.¹ Even though these improvements warrant further market adoption, limitations on power output for the back-side photovoltaic portion of the panels are driven by lack of irradiance energy from sunlight being able to access these photovoltaic cells.

Observations have been reported indicating that the most improved output of such panels are specifically during winter months.⁷ One key pursuit to enhance bifacial photovoltaic module output performance is to maximize an albedo environment. Current data supports that lighter colored ground and or white reflective surfaces on the ground below current array projects that deploy such types of panels improve output. However, no reports of any specific reflective panels deployed within a three-dimensional enclosed low-profile array system have been tested. This hypothesis was tested in a spectral albedo model, where it was predicted that power output for a bifacial silicon solar cell surrounded with different materials would materially improve the lighter the color of reflective surfaces.⁸ The technology described herein recognizes that reflective surfaces within a photovoltaic assembly structure aimed at reflecting irradiance energy to the back bifacial panels will improve power output results. Certain embodiments include other components such as trusses and adjustable reflectors as described in more detail hereinbelow.

Certain embodiments of truss arrangements are intended to be marketed as a “floating advanced support truss (FAST)” system and certain embodiments of deflecting panels are intended to be marketed as a “ballast advanced deflective energy (BLADE) system.” It is envisioned that these FAST and BLADE systems will include components constructed of plastics such as polypropylene and other materials formed from by-products of hydrocarbon refining. These low-cost materials are intended to improve capital expenditures during construction of large solar array projects while also benefiting decommissioning of these projects. Embodiments of ballast containers may be provided with coupling or fastening structures to facilitate connection to the trusses and/or reflectors to construct a solar panel assembly for deployment in solar array projects. The integration of such components would intend to offer unique structural advantages as well as easier installation, deployment and decommissioning, all of which drive the refined and improved value and investment hypothesis for such novel systems.

In such integrated assembly embodiments, directed reflection of targeted sunlight irradiance onto the back of bifacial photovoltaic panels can be provided by reflector components connect to trusses. A series of such reflector components can facilitate and optimize irradiance energy to the back of north, top and south facing bifacial panels.

In most existing solar projects that utilize reflectors, such projects use large Fresnel and or parabolic trough photovoltaic systems. In these systems, imperfect focusing of sun light can lead to energy loss.

In some existing projects, the reflector components are constructed from highly reflective aluminum products. Although very effective, the material costs of these reflectors are high. In some embodiments, the reflector components are formed of petrochemical by-products and/or polypropylene materials. These materials are lower in cost than aluminum products. The specific materials used in this embodiment are developed for high irradiance with high reflective properties to further enhance in delivering additional reflective irradiance properties and power output to the north, passive side of such panels in northern latitudes, and south, passive side in southern latitudes, of the housing units aligned in front of an array. Such reflector components may be mounted or formed within various embodiments of ballast containers and configured for convenient access to fold, slide or move out and away in the event of serious snowfalls and or windstorms that would impact performance of such system or if such components require need cleaning.

### Description of Example Embodiments

### Solar Panel Assemblies

Example embodiments are described herein in the context of examples of three-dimensional low profile solar electrical generator assemblies which have been described in U.S. Provisional Patent Application No. 63/039,775, incorporated herein by reference in its entirety.⁹ The same reference indicators will be used to the extent possible throughout the drawings and the following description to refer to similar components or components providing similar functions. However, it is to be understood that embodiments of the technology described herein may be applied to other solar electrical generation assemblies having structures and features different from those described in U.S. Provisional Patent Application No. 63/039,775.⁹

In the interest of clarity, not all of the routine features of the implementations described herein are shown and described. It will, be appreciated that in the development of assembly embodiments, numerous and iterative implementation-specific decisions may be made in order to achieve optimal land use, shadow characteristics and power output for a developer's specific goals, such as compliance with application- and business-related constraints, and that these specific goals will vary from one implementation site to another and from one developer to another. Moreover, it will be appreciated that such development efforts might be complex and time-consuming but would nevertheless be a routine undertaking of engineering for those of ordinary skill in the art having the benefit of this disclosure.

As described herein, various embodiments of a low-profile three-dimensional solar electrical generator assembly are described to facilitate subsequent understanding of embodiments of the ballast support apparatus and related components for solar electrical generator systems. Certain commercial assemblies are expected to be marketed as a Maximized Energy Reference system (MER). The term “MER” is derived from the ancient Egyptian word for pyramid, the symbol of power, strength and durability.

For the purposes of description herein, reference may be made to the directions of “north”, “south”, “pole-facing” and “equator-facing” panels. Generally, north refers to a direction towards the north pole and south refers to a direction towards the south pole. The term pole-facing refers to a direction that is towards either the north pole or the south pole and the term equator-facing refers to a direction towards the equator. In the context of photovoltaic systems located in the northern hemisphere, pole-facing refers to a direction towards the north pole and for photovoltaic systems located in the southern hemisphere, pole-facing refers to a direction towards the south pole. Equator-facing always refers to a direction generally towards the equator.

Embodiments of the system each have a plurality of angled panels assembled to form a single integrated base solar unit.

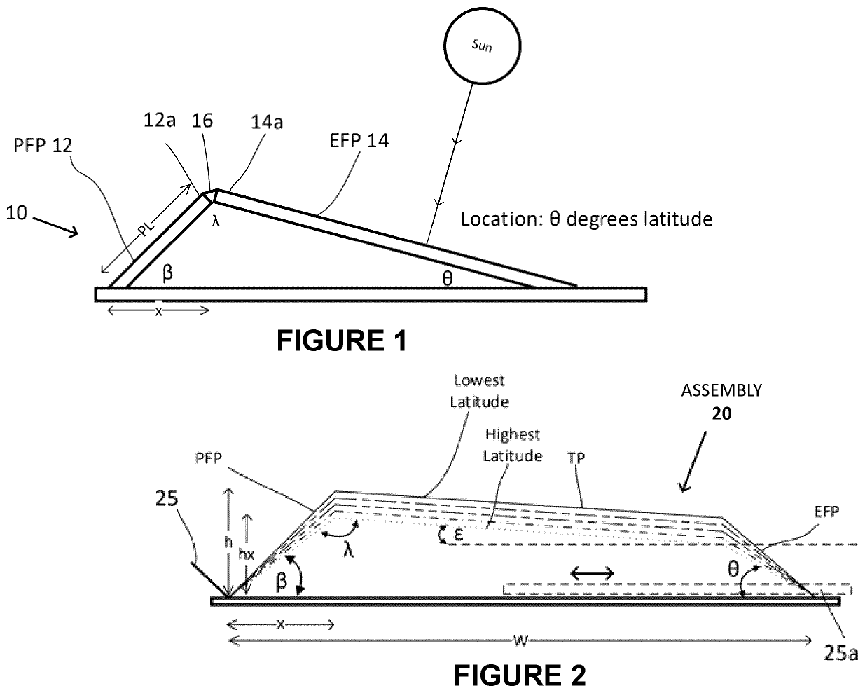

Referring now to FIG. 1, there is shown one embodiment of an assembly 10 which has two panels including a pole-facing panel (PFP) 12 (e.g. north-facing) and an equator-facing panel (EFP) 14 (e.g. south-facing). As shown, the EFP is generally oriented towards the equator and is angled with respect to the horizontal at angle, θ. The angle θ may be selected in order that it roughly corresponds to the latitude of the deployment for deployments at less than 30 degrees latitude. However, for deployments at greater than 30 degrees latitude, the angle θ will typically not exceed 30 degrees.

The system may include a suitable hinge or fixed connection bracket 16 between the two panels. The PFP provides support to the equator side 14a of the EFP thus elevating the EFP to the correct angle θ for the deployment. The PFP is angled with respect to the horizontal at an angle, β, which will be an acute angle. As shown in Table 1, typical fixed tilt angles are shown for an array across a year at different latitudes using the rules:
a. For latitudes below 25°, tilt angle=latitude×0.87.
b. For latitudes between 25° and 50° tilt angle=latitude×0.76+3.1 degrees

TABLE 1
Approximate Tilt Angles for Fixed Angle Arrays

| | | Avg. insolation |
|---|---|---|
| | Full year | on panel |
| Latitude | angle | kWh/m2/day |
| 0° (Quito) | 0.0 | 6.5 |
| 5° (Bogotá) | 4.4 | 6.5 |
| 10° (Caracas) | 8.7 | 6.5 |
| 15° (Dakar) | 13.1 | 6.4 |
| 20° (Mérida) | 17.4 | 6.3 |
| 25° (Key West, Taipei) | 22.1 | 6.2 |
| 30° (Houston, Cairo) | 25.9 | 6.1 |
| 35° (Albuquerque, Tokyo) | 29.7 | 6.0 |
| 40° (Denver, Madrid) | 33.5 | 5.7 |
| 45° (Minneapolis, Milano) | 37.3 | 5.4 |
| 50° (Winnipeg, Prague) | 41.1 | 5.1 |

The length of the PFP will be determined by the anticipated latitude of deployment wherein the length of the PFP is chosen such that the angle @ generally corresponds to the latitude (typically a few degrees less for latitudes up to about 30 degrees and up to about 30 degrees for latitudes up to about 50 degrees) and the PFP angle β will preferably be less than 45 degrees. As noted, the angle θ will typically not exceed 30 degrees and the angle β will not exceed 45 degrees in order to reduce wind load effects on the polar facing side of the system. The connection 16 may be a hinge, enabling adjustment of the angle θ to an optimal angle and may also include leg extensions or other adjustable devices (not shown) to assist in adjustment of the length and angle.

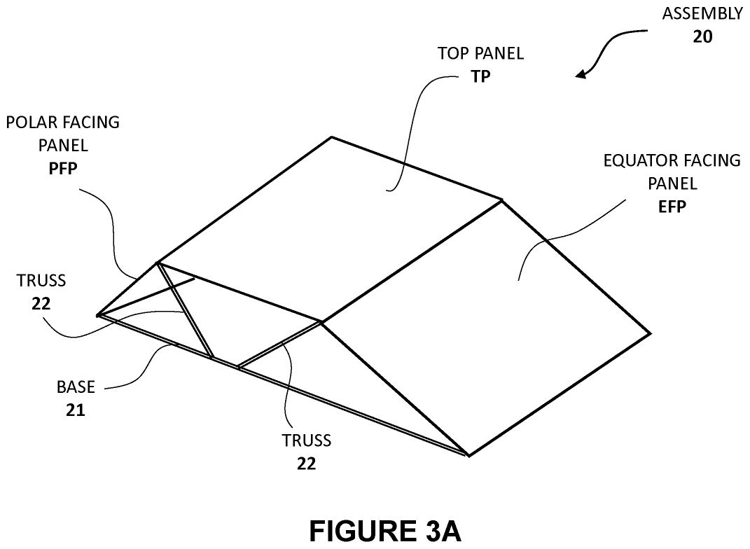

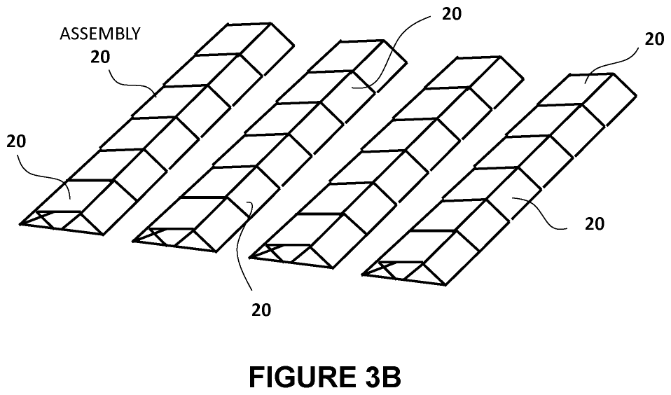

FIGS. 2 and 3 show a 3-panel embodiment having a PFP, EFP and TP. The TP is at an angle ε with respect to the horizontal and the EFP defines an angle θ with respect to the horizontal thus providing for an asymmetric structure in cross-section.

In some embodiments, the dimensions of an asymmetric system will generally address the following design principles:
Lower latitude assemblies can be taller as the sun is higher in the sky and shadows cast between adjacent assemblies are smaller.
Higher latitude assemblies will be lower in height as the sun is lower in the sky and the height reduced to minimize shadows from one assembly to another.
Low and high latitude assemblies will have a TP sloping towards the equator at an angle sufficient to allow drainage of water. Typically, this angle will in the range of about 5-10 degrees.
If the assembly includes side panels (preferred), the side panels will have a maximum base length x generally corresponding to the base length x of the PFP.
The height h of an assembly will generally correspond to the base length x.
The total width W (typically the cross-sectional width through the EFP, TP and PFP in the pole-equator direction) of an assembly will be approximately 3-5×.
The total length L (typically the east-west direction) of a given assembly will be a multiple of W, typically 0.8-10⁺ W. There is no particular upper limit on L and will be determined by practical features of an installation.
The location of the intersection between adjacent side panels on one side of an assembly will vary depending on the latitude. Generally, at a lower latitude, the location of intersection will be closer to the PFP and at a higher latitude, the location of intersection will be further away from the PFP.

FIG. 2 shows how an asymmetric assembly may be designed for different latitudes. As shown, 5 different assembly profiles are shown with different line styles where the lowest latitude assembly may have a height h and the highest latitude assembly has a lower height hₓ. As shown, for each design, the TP has a fixed slope towards the equator (to allow water drainage). Thus, as the height is lowered, both the EFP and PFP become shorter. The total height will generally consider overall height relative to an adjacent assembly such that the time that shadows are cast during the day from one assembly onto another is eliminated or reduced. Practically, the height h will be in the range of about 18 to about 36 inches. FIG. 3A is a perspective view indicating how the asymmetric assembly 20 is supported by a base member 21 extending between panels PFP and EFP, and angled trusses 22 extending from top panel corners to the base member 21. FIG. 3B illustrates how a series of assemblies 20 can be extended and arranged in a solar array installation.

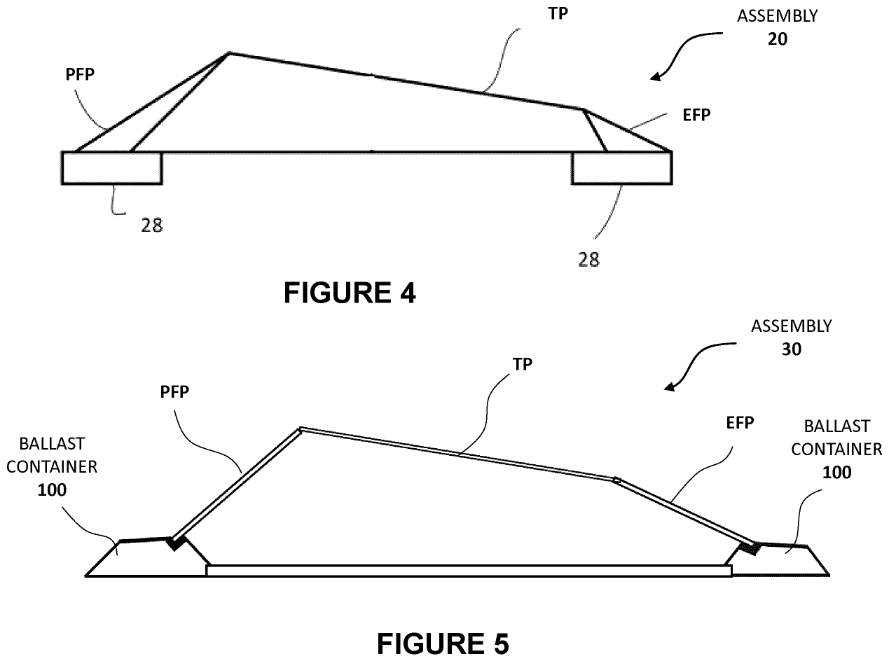

Turning now to FIG. 4, there is shown an assembly 20 which was originally described in commonly owned U.S. Provisional Patent Application No. 63/039,775.9 This assembly 20 includes a generic perimeter foundation system provided by foundations 28. In the side view shown in FIG. 4, the ends of the foundations 28 are shown in the side view profile of the assembly 20. The inventors have recognized that it would be advantageous to provide such generic solar panel assembly foundations 28 with additional features to allow them to be easily transported to solar electrical generation installations and placed on the ground without a requirement for burying the foundations 28 within the ground or staking the foundations 28 to the ground. The inventors also recognized that foundations resting on the ground would also provide a highly useful substrate for incorporation of additional features for improving the collection of solar energy and other practical aspects such as protection of sensitive components from the weather elements. This recognition has led to development of new foundation embodiments which are described hereinbelow.

### Ballast Containers

FIG. 5 illustrates a side view of another photovoltaic assembly embodiment 30 which, like assembly 20, includes a polar facing panel PFP, a top panel TP and an equator facing panel EFP. Instead of generic foundations 28, this assembly 30 includes a pair of ballast containers 100 which function as support devices for the panels PFP, TP and EFP of the assembly 30. It is to be understood that the ballast containers 100 and other embodiments of ballast containers including, but not limited to ballast container embodiments 200, 300, 400, 500, 600, 700, 1000, 1100, 1200 and 2100 described hereinbelow, may be used in alternative solar panel assemblies other than the assemblies described herein as examples. Various embodiments of ballast containers may be variable in size and shape and are intended to be simply placed on the ground (“floating” on the ground) instead of being buried or staked into place, with ballast being placed therein to increase the mass to a sufficient extent to prevent the assembly from being moved by wind loading forces. In one preferred embodiment, the ballast material is water. In other embodiments, the ballast is another flowable material such as sand or gravel, for example.

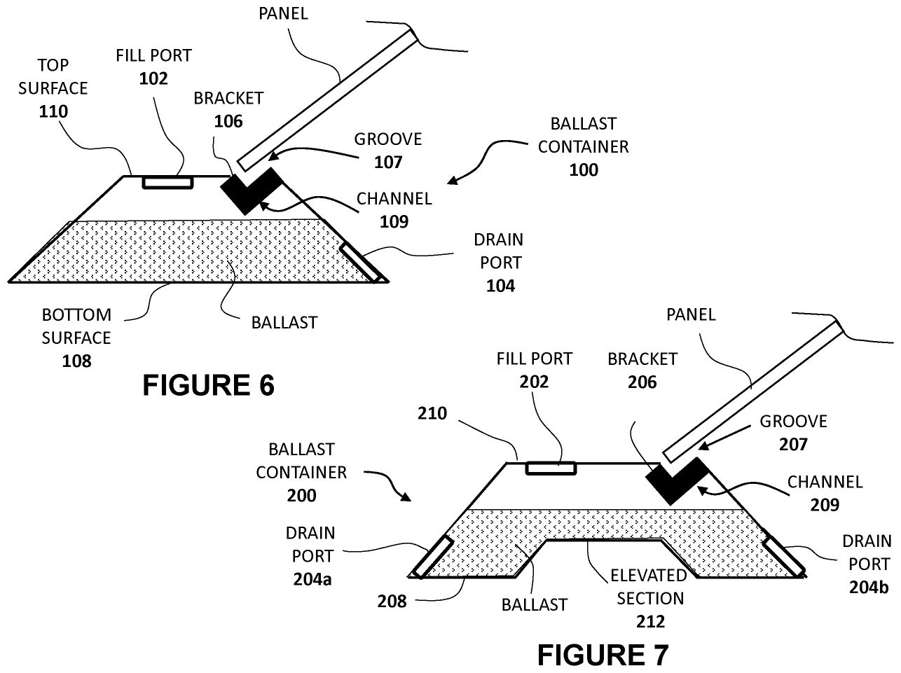

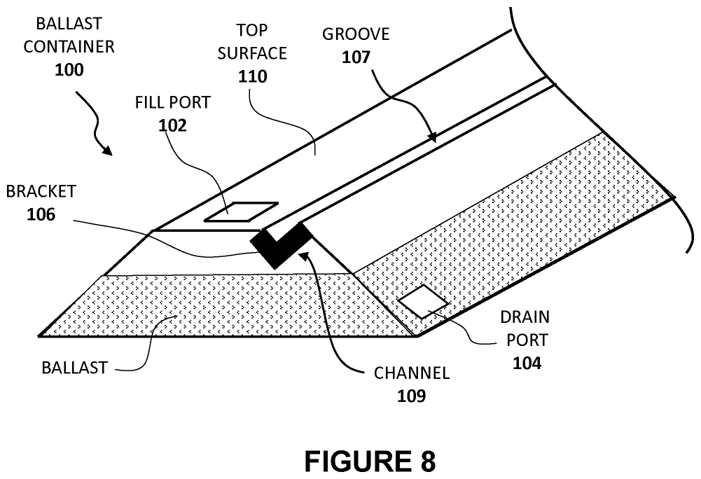

Selected features of the first ballast container embodiment 100 are illustrated in FIGS. 6 and 8, where it is seen that the ballast container 100 is provided with an upper fill port 102 and a lower drain port 104 to permit a flowable ballast such as water to be poured into the ballast container 100 to load it with ballast and to permit the ballast to be drained from the ballast container 100 if it is desired to disassemble the assembly, for any reason, such as for example, adjustment of placement of photovoltaic arrays formed from the assemblies, replacement of individual assemblies or decommissioning of a photovoltaic power generation installation.

In the example embodiment shown in FIGS. 6 and 8, the fill port 102 is formed in a top surface 110 of the ballast container 100. Alternative embodiments may have a fill port formed in a side wall of the ballast container 100. An upper region of the ballast container 100 has a channel 109 formed therein, which holds a bracket 106 to provide a groove 107 to hold a lower edge of a solar panel, as generally illustrated in FIG. 6. This ballast container 100 includes a flat bottom surface 108. In alternative embodiments, the groove may be formed directly in an outer surface of the ballast container and in such embodiments, a separate groove containing structure such as a bracket, will not be required.

FIG. 7 illustrates another ballast container embodiment 200 which has similar features as embodiment 100, including a fill port 202, a pair of drain ports 204a, b, and a bracket 206 in a channel 209 which presents a groove 207 to retain a solar panel. This ballast container embodiment 200 includes a bottom surface 208 with an elevated section 212 and a pair of drain ports 204a, b. The elevated/recessed section 212 is useful in situations where it may be helpful to install a lifter such as a jack to either level the ballast container 200 if it is required to be placed on unlevel ground, or to raise the entire ballast container 200 to move it using a pallet jack, forklift or another type of mobile lifter after ballast is installed therein. The elevated section 212 permits such a lifter to contact the underside of the ballast container 200 to enable the lifting operation to be performed, for example by the forks of a forklift.

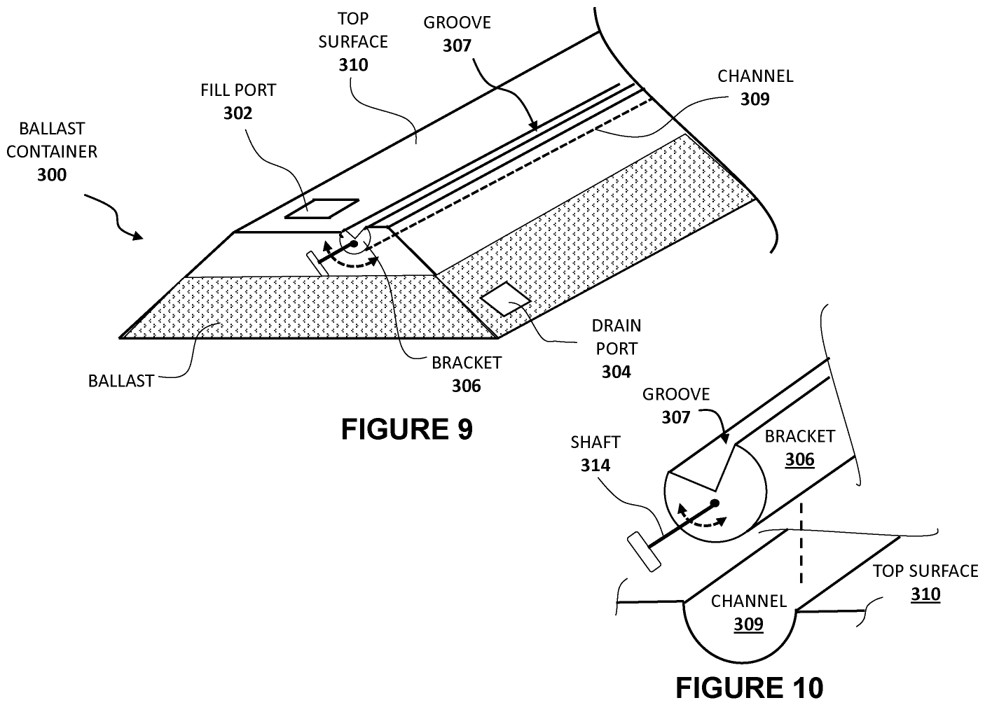

FIG. 9 illustrates another ballast container embodiment 300 which has similar features as embodiment 100, including a fill port 302, a drain port 304, a bracket 306 in a channel 309 which presents a groove 307 to retain a solar panel. In this ballast container embodiment 300, the channel 309 is radiused, as seen more clearly in the exploded perspective view of FIG. 10. The bracket 306 has a cylindrical profile to match the radiused channel 309 and includes an angled cut-out to form the groove 307. There is a shaft 314 extending from a central point of the end of the radiused bracket 306. As shown more clearly in the partial exploded view of FIG. 10, rotation of the shaft 314 will change the orientation of the groove 307, thereby changing the angle at which a supported solar panel will be disposed. In some embodiments using a radiused channel 309 and bracket 306, the rotation may be calibrated with markings and set points (not shown) to provide specific angles for use at specific latitudes as recommended for specific assembly configurations as described hereinabove with respect to FIG. 2, thereby facilitating proper installation of solar panel assemblies without a need to make measurements and significant adjustments.

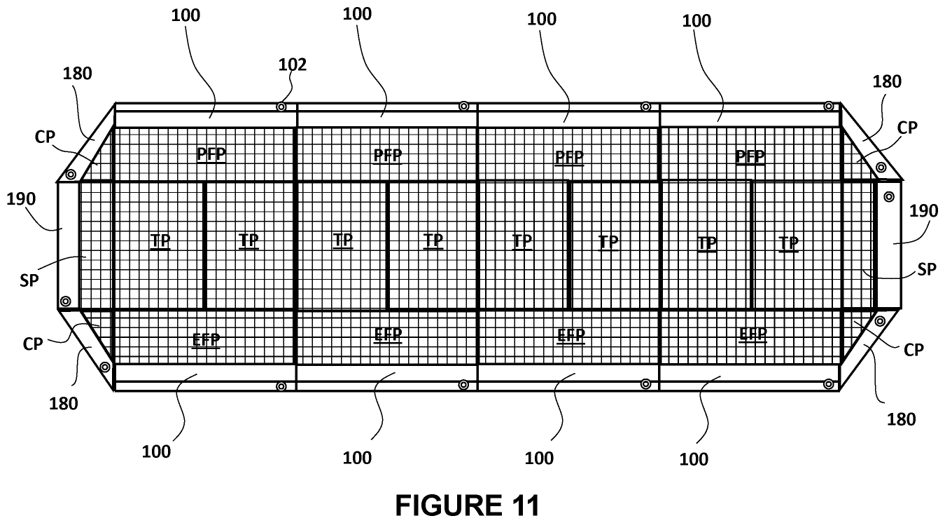

FIG. 11 is a top view illustration of a series of four photovoltaic assemblies formed using the ballast container embodiment 100, as well as smaller ballast containers 180 and 190 for supporting corner panels CP and side panels SP, respectively, to provide an extended assembly. Each one of the four assemblies include one polar facing panel PFP, two top panels TP and one equator facing panel EFP which are supported by opposed ballast containers 100. The ballast containers 100 of adjacent assemblies in the series are placed directly adjacent to each other and may be connected to each other if deemed advantageous. Such a series of photovoltaic assemblies may be made longer with placement of additional assemblies if additional land area is available. A similar series of assemblies may be constructed using different embodiments of ballast containers or different arrangements of panels.

Embodiments of ballast containers may be formed of rigid thermoplastics such as high-density polyethylene (HPDE), polyvinyl chloride (PVC), polypropylene, or cellulose based materials, for example, which can be formed by injection molding or additive manufacturing. In some embodiments, the ballast containers have a length sufficient to support common lengths of solar panels, such as about 72 inches (about 183 cm) with sufficient interior volume to hold about 500 to about 1,000 pounds (about 226 to about 453 kg) of water. Ballast containers may be formed with compartments with separate fill/drain ports to minimize effects in the event one compartment develops a leak.

Additional embodiments of ballast containers are described hereinbelow, in context of the provision of additional components providing additional advantages to photovoltaic assemblies.

Ballast Containers with Reflectors

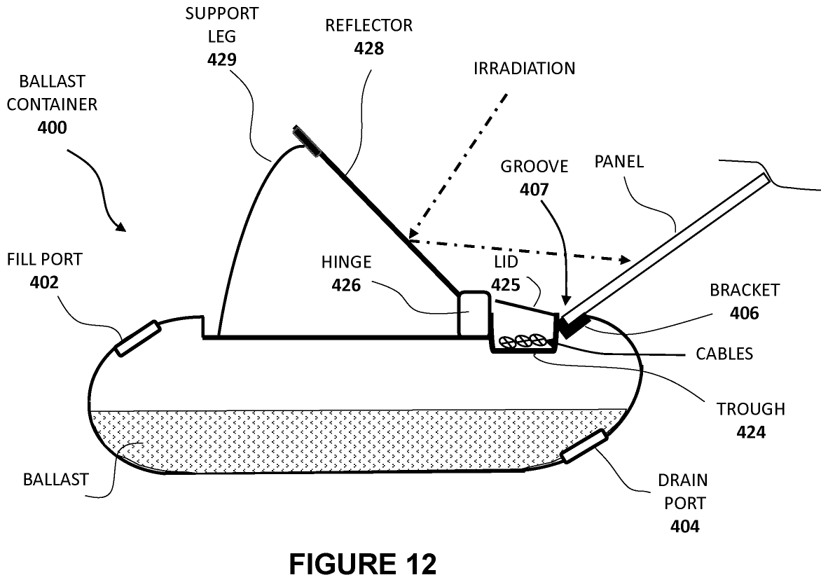

Another ballast container embodiment 400 is illustrated in FIG. 12. This embodiment includes a similar fill port 402, drain port 404, bracket 406 and groove 407 for holding a panel. This embodiment 400 differs in having a curved side profile, as well as a reflector 428 mounted on a hinge 426 to the left of the bracket 406. The reflector may have a surface formed of a mirror or other reflective material. When deployed and supported by support leg 429, The reflector 428 receives and directs additional solar energy towards the panel. A trough 424 with a lid 425 is located between the hinge 426 and the bracket 406. The trough 424 is provided to hold conducting cables through which electrical current generated by the photovoltaic panels is transmitted. The lid 425 over the trough 424 provides protection of the cables from the weather elements. The trough feature 424 of this ballast container embodiment 400 may be incorporated into alternative embodiments of ballast containers which do not include a reflector.

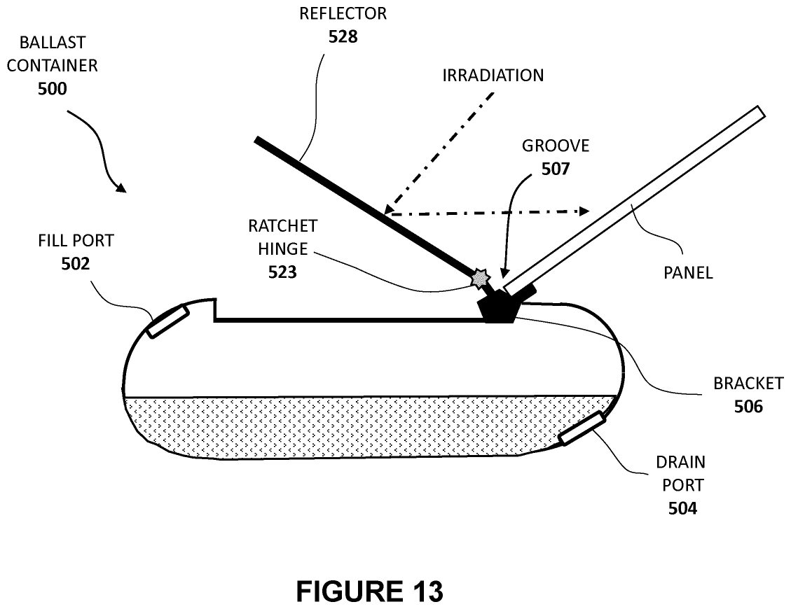

Another ballast container embodiment 500 is illustrated in FIG. 13. Like embodiment 400, this ballast container 500 has a curved side profile, a similar fill port 502 and a similar drain port 504. However, there is a bracket 506 forming a groove 507 which is connected to a reflector 528 via a ratchet hinge 523. The ratchet hinge 523 is configured to adjust the angle of disposition of the reflector 528 in defined increments representing set-points to optimize reflectance in response to local environmental conditions.

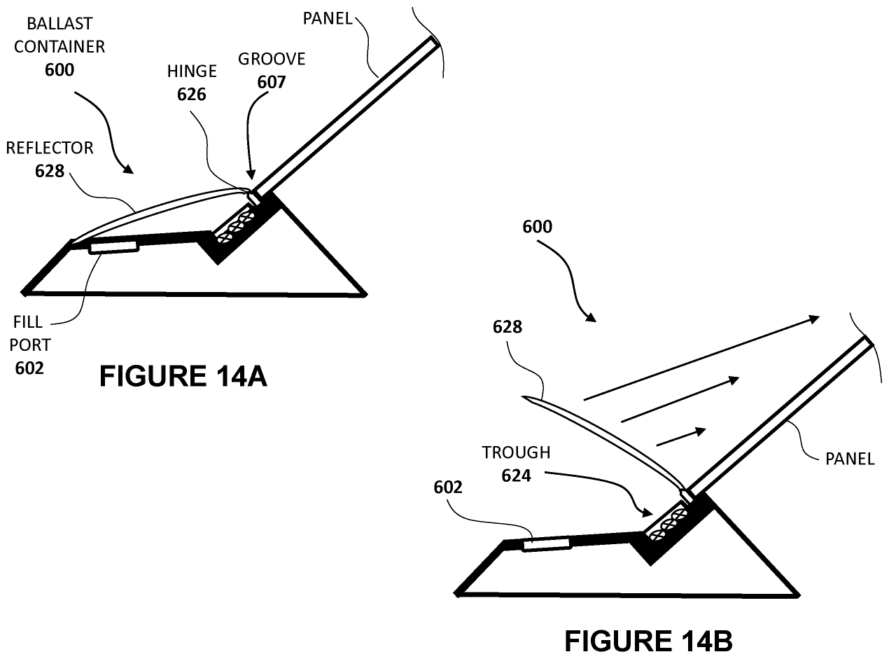

An additional embodiment 600 of a ballast container with a curved reflector 628 is shown in FIGS. 14A and 14B, where the curved reflector 628 is retracted with an outward end against an upper surface of the ballast container 600 in FIG. 14A and extended with its outward end pointing up and leftward in FIG. 14B. It is seen in these illustrations that the groove 607 which holds the panel is formed by a sloped upper surface of the ballast container and a surface of a reflector hinge 626. The groove 607 therefore remains constant whether the curved reflector 628 is retracted or extended. It is also seen that the curved reflector 628 also functions as a lid to provide protection of the fill port 602 and the cable trough 624.

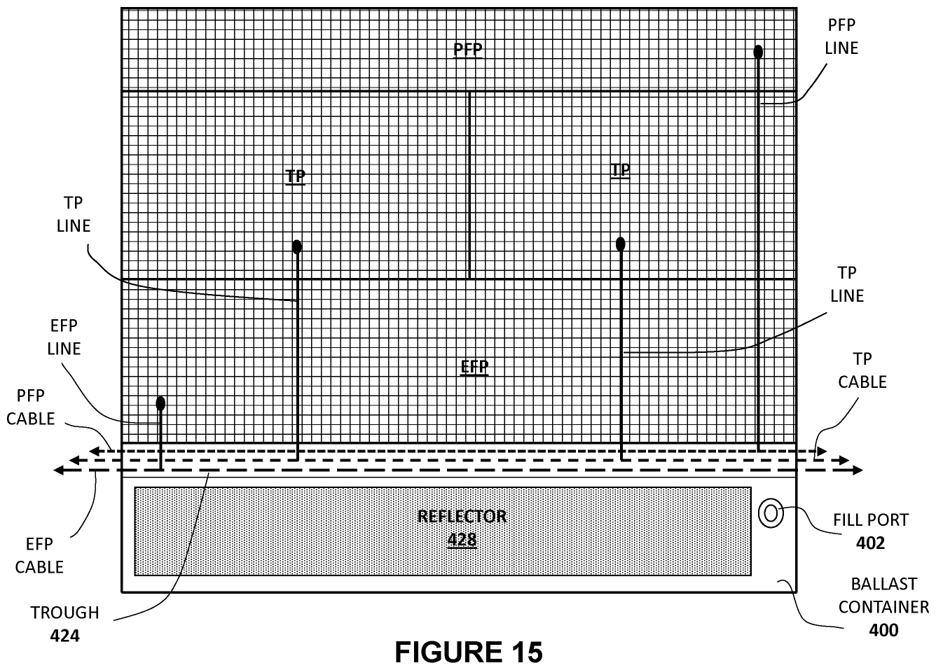

FIG. 15 is an illustration of a partial top view of a photovoltaic assembly supported by ballast container 400, which shows electrical transmission lines emanating from panels PFP, TP, and EFP and extending downward to join three corresponding transmission cables held in the cable trough 424 of ballast container 400. It is to be understood that the transmission lines emanating from the panels PFP, TP, and EFP are located below the panels PFP, TP, and EFP such that they are protected from the elements and do not block collection of solar energy. In some embodiments, it may be advantageous to include additional side ports in the ballast container near the cable trough 428 so that the lines can enter the cable trough from the side. It is to be understood that similar arrangements may be provided with other embodiments of ballast containers which include a cable trough, such as ballast container 600, for example, which includes cable trough 624.

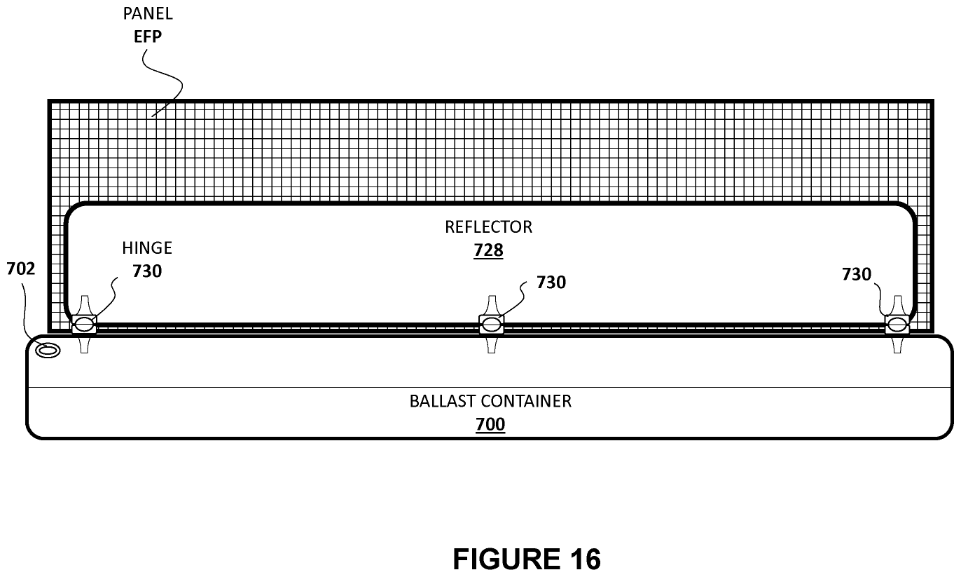

FIG. 16 is a side elevation profile of another embodiment of a ballast container 700 indicating the position of a fill port 702 and connection of a reflector 728 to the ballast container 700 using three hinges 730 which each include fasteners, such as eyehole grommets, for example, to make connections to suitable structures connected to or formed integrally in the reflector 728 and the ballast container 700.

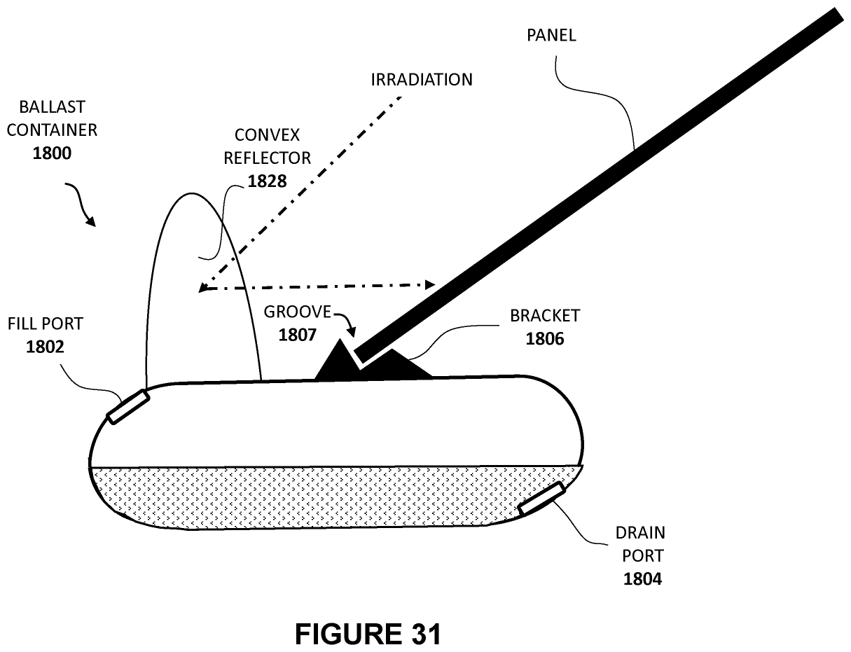

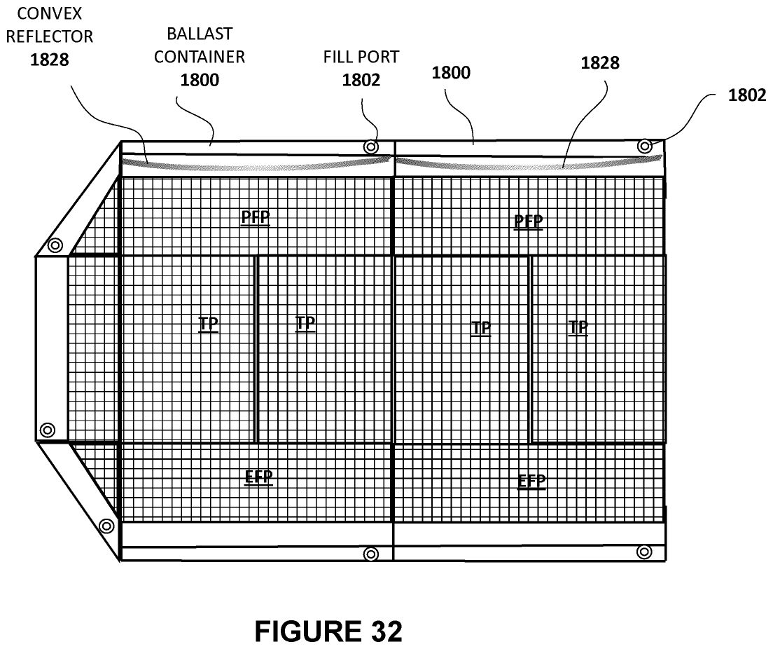

Another embodiment of a ballast container 1800 having a reflector is shown in FIGS. 31 and 32. It is seen in FIG. 31 that this embodiment 1800 has the same general shape as ballast container embodiments 400 and 500 and includes a fill port 1802, a drain port 1804 and a bracket 1806 providing a groove 1807 to support a panel. This embodiment 1800 includes a convex reflector 1828 which is mounted at the left end of the top surface of the ballast container 1800. It is expected that this convex reflector shape arrangement will improve collection of solar irradiation at the polar facing panel of a MER system. In some embodiments, the convex reflector 1828 is connected to the top surface of the ballast container using any kind of reversible attachment mechanism, such as a snap-in latch connectors fixed to the ballast container 1800 or formed integrally in the ballast container 1800. In some embodiments, the reflector 1828 is covered with a flexible reflective material, such as Omni-Heat™ Reflective material. It is predicted that solar array assemblies formed using this ballast container embodiment 1800 will permit optimization of spacing between assemblies to about 3.5 feet (about 1 meter). It is seen in FIG. 32, which shows a section of an assembly, that the convex reflector 1828 extends across substantially the entire length of the ballast container 1800.

### Support Components for Photovoltaic Assemblies Using Ballast Containers

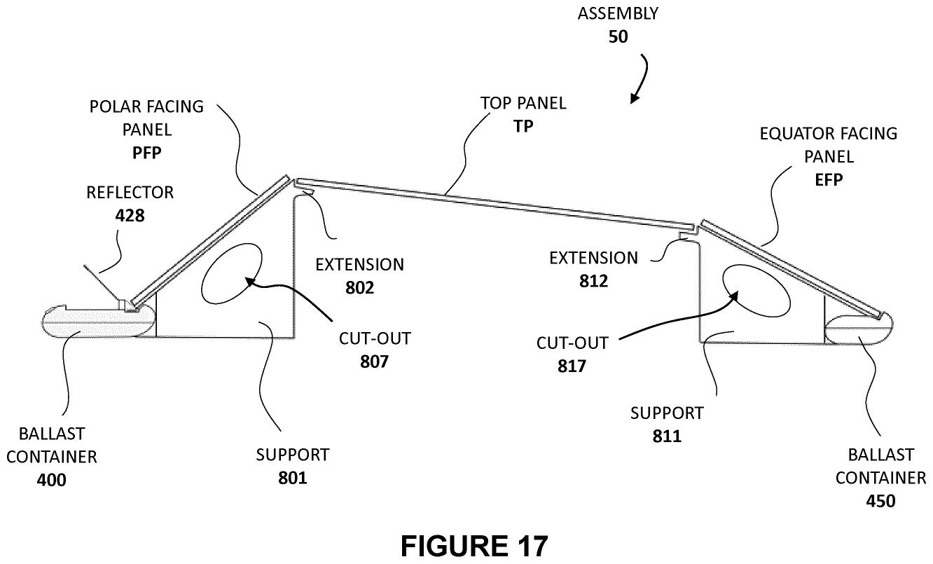

The present inventors have recognized that photovoltaic assemblies can benefit from having additional stabilization provided by additional support structures which, in some embodiments can be mounted, connected to, braced by or associated with various embodiments of ballast containers. One example of a photovoltaic assembly 50 is illustrated in an end elevation view in FIG. 17. This assembly 50 includes ballast container 400 on the left side and a simplified embodiment of a curved profile ballast container 450 on the right side, which does not include a reflector. Panel support structures 801 and 811, each having an outward extension 802, 812 are placed adjacent to the ballast containers 400 and 450. The PFP and the EFP are retained in respective grooves in the ballast containers 400 and 450 and rest against the angled upper surfaces of the panel support structures 801 and 811 and the TP is placed such that its longitudinal edges rest upon the extensions 802, 812 of the panel support structures 801 and 811. In this embodiment, the panel support structures 801 and 811 have oval-shaped cut-outs 807 and 817 which define an upper narrow portion of the panel support structures 801 and 811, which can function as a convenient carrying handle. While not illustrated specifically in FIG. 17, it is to be understood that the support structures of these embodiments are intended to be relatively narrow in dimensional width relative to their lengths as illustrated in FIG. 17.

The main upper surface of each of the panel support structures 801 and 811 is sloped. It is seen in FIG. 17 that the slope of pane support structure 801 is greater than the slope of panel support structure 811. It is envisioned that construction of assemblies will include options to use different supports with different slopes according to the solar irradiation conditions at various locations, as outlined hereinabove, with respect to latitude calculations listed in Table 1. Therefore, certain embodiments of the technology include kits which may include one or more sets of ballast containers according to any of the embodiments described herein in combination with a series of supports according to any of the support embodiments described herein, with the members of the series of supports having different upper slopes to provide support for panels at different angles. The kits may include any of the components described herein and may also include instructions for constructing photovoltaic assemblies formed of ballast containers and separate panel support structures.

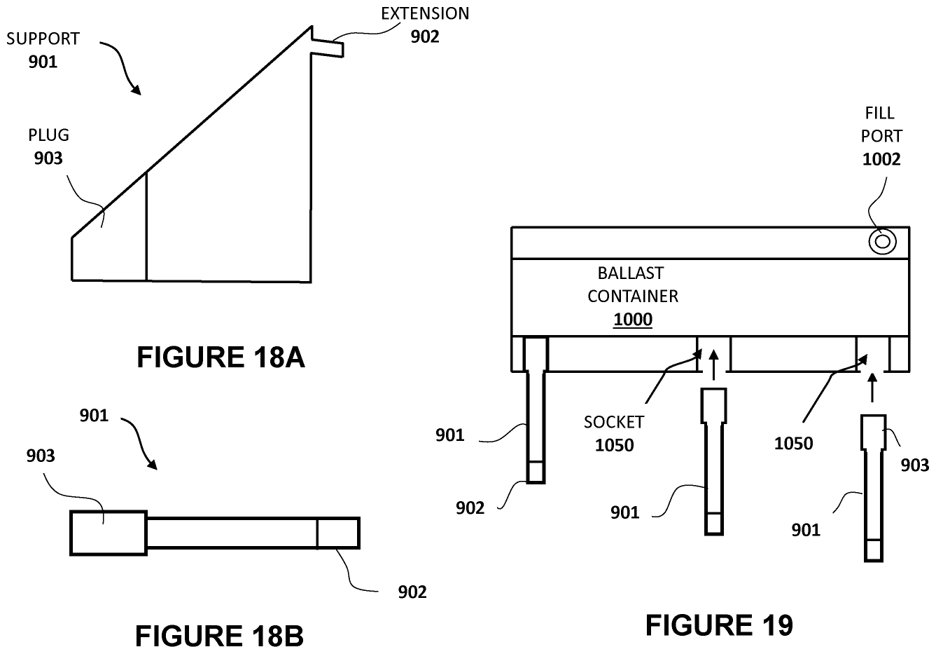

FIGS. 18A and 18B show a side elevation view and a top view, respectively, of another embodiment of a panel support structure 901 intended for deployment in a similar manner as illustrated for panel support structure 801 in FIG. 17. This embodiment 901 includes an extension 902 to retain a top panel and an opposed plug end 903. FIG. 19 illustrates how this panel support structure embodiment 901 is connected via the plug end 903 to another embodiment of a ballast container 1000 via sockets 1050 formed therein. Other types of complementary coupling structures may be used as alternatives to plug and socket arrangements. While FIG. 19 illustrates the presence of three panel support structures 901, alternative embodiments may include more or fewer panel support structures 901 connected to the ballast container 1000. It is to be understood that an assembly with these components will also include an opposed ballast container with a similar set of panel support structures which may have a different height dimension as illustrated for assembly 50 of FIG. 17.

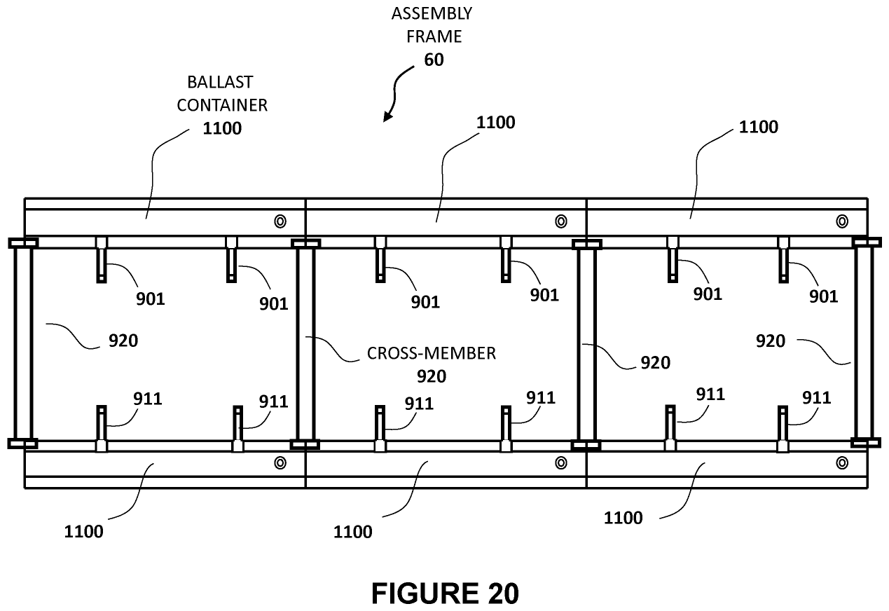

FIG. 20 is a top view of an assembly frame 60 suitable for supporting a set of panels (not shown) in a manner similar to the arrangement illustrated in FIG. 17 for assembly 50. Assembly frame 60 is formed of connected and opposed ballast containers 1100 with the upper series of ballast containers 1100 (in the view shown) having two connected supports 901 for each of the three ballast containers 1100. The opposed lower series of ballast containers 1100 (in the view shown) likewise have two connected panel support structures 902 for each of the ballast containers 1100. The frame 60 further includes four cross members 920 connected to opposed ballast containers 1100 and disposed at regular intervals to provide additional stability. The cross members 920 may be provided with any kind of connection mechanism, such as for example, a plug and socket arrangement wherein the socket is formed in the ballast container 1100. In the frame embodiment 60 illustrated in FIG. 20, the two inner cross members 920 have ends which connect to two adjacent ballast containers 1100 to provide additional stability. This optional arrangement requires that partial sockets are formed at the ends of the ballast containers 1100, which, when connected, form a complete socket to accept the plug end of a cross member 920.

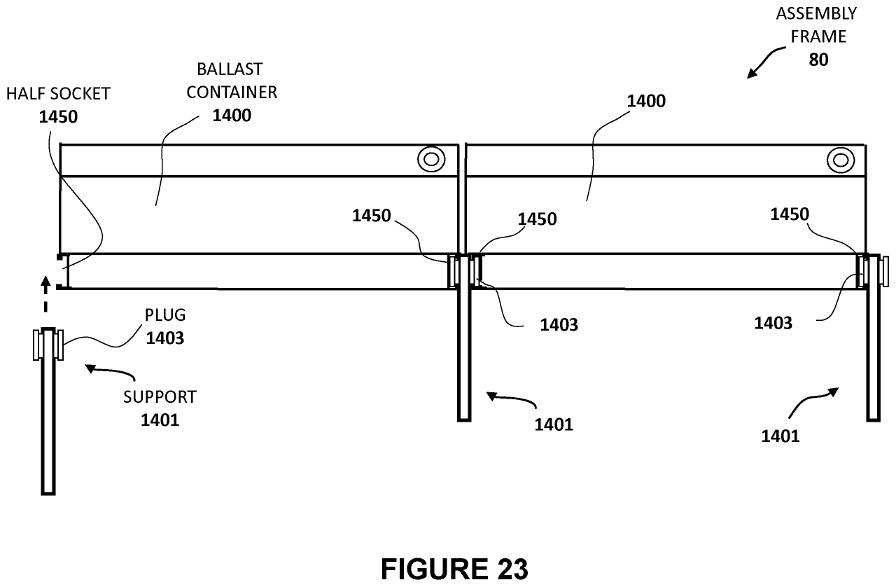

Turning now to FIG. 23, this figure shows a partial top view of an assembly frame based on another embodiment of a ballast container 1400 which includes opposed end half-sockets 1450 which form a complete socket when two ballast containers 1400 are placed adjacent to each other as shown. The complete socket is dimensioned to receive a plug end 1403 of a support 1401 in a manner similar to the arrangement illustrated in FIG. 20 for the cross members 920.

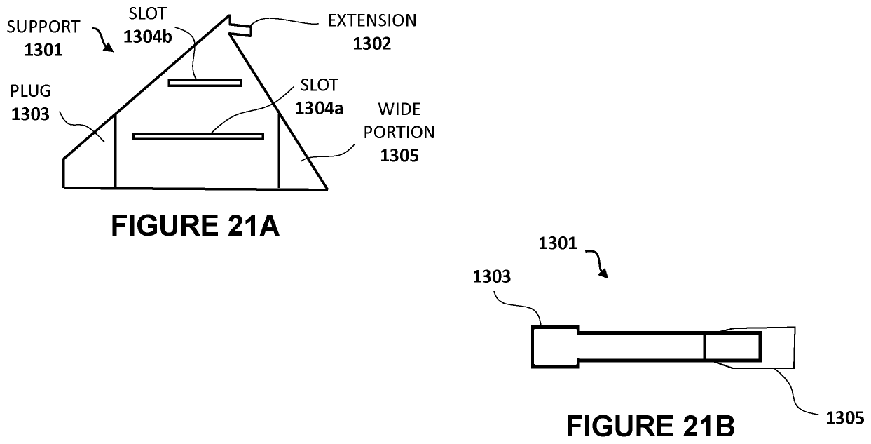

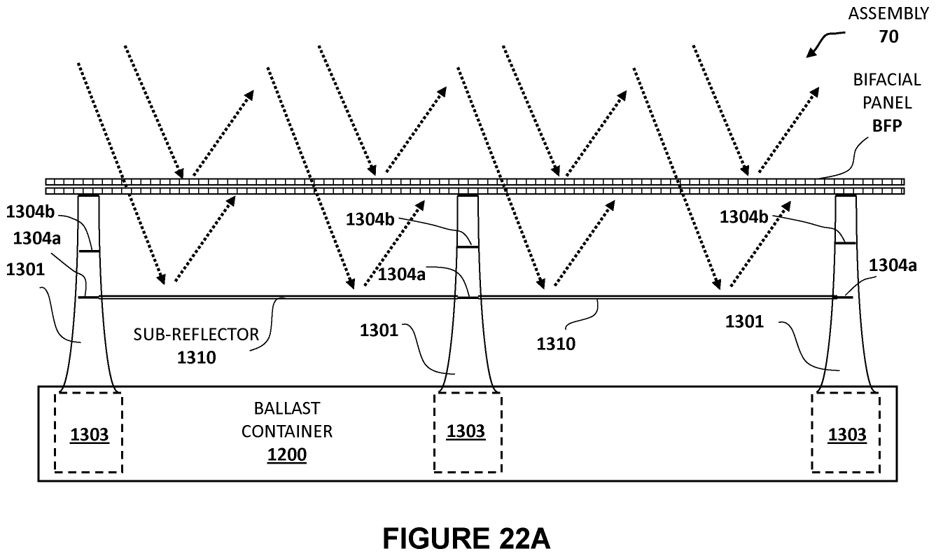

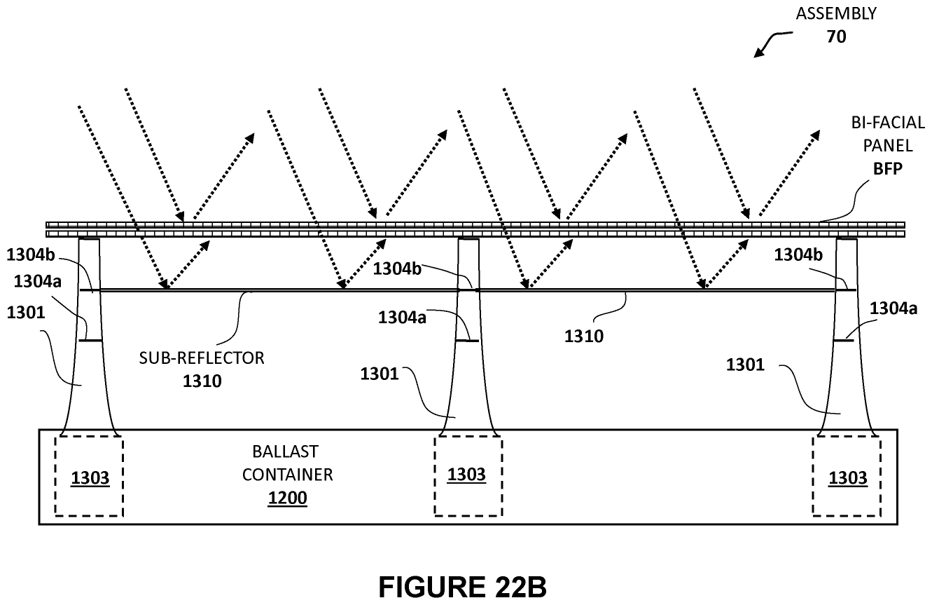

FIGS. 21A and 21B illustrate side elevation and top views, respectively, of another panel support structure embodiment 1301. This embodiment 1301, like embodiments 901 and 911, includes an extension 1302 and a plug 1303, as well as a wide portion 1305 at the end opposite the plug 1303. The wide portion 1305 provides the panel support structure 1301 with additional stability. This embodiment of panel support structure 1301 is provided with features to collect additional solar energy. Support 1301 also includes two slots 1304a, b which is included to provide a means of connection of a sub-reflector 1310 as illustrated in the side elevation views of FIGS. 22A and 22B of another photovoltaic assembly embodiment 70, which shows two sub-reflectors 1310 connected between adjacent supports 1301. Alternatively, support 1301 may have a single slot. In FIG. 22A, the sub-reflectors 1310 are connected to the supports 1301 via slot 1304a and in FIG. 22B, the sub-reflectors 1310 are connected to the supports 1301 via slot 1304b. The distance between the sub-reflectors 1310 and the bi-facial panel PFP is greater in the assembly 70 of FIG. 22A than the distance between the sub-reflectors 1310 and the bi-facial panel PFP in the assembly 70 of FIG. 22B The sub-reflectors 1310 are used when an assembly includes one or more bi-facial panels BFP and reflects any radiation passing through an upper face of the bi-facial panel back to the lower face of the bi-facial panel, to capture this extra energy. As described above, bi-facial collection of light on both sides of a panel can provide more power production without expanding system footprints or significantly reconfiguring the panels. Some alternative embodiments may include one or more additional longitudinal slots for alternative placement of the sub-reflectors even closer to the bi-facial panel(s) or even farther away from the bi-facial panels.

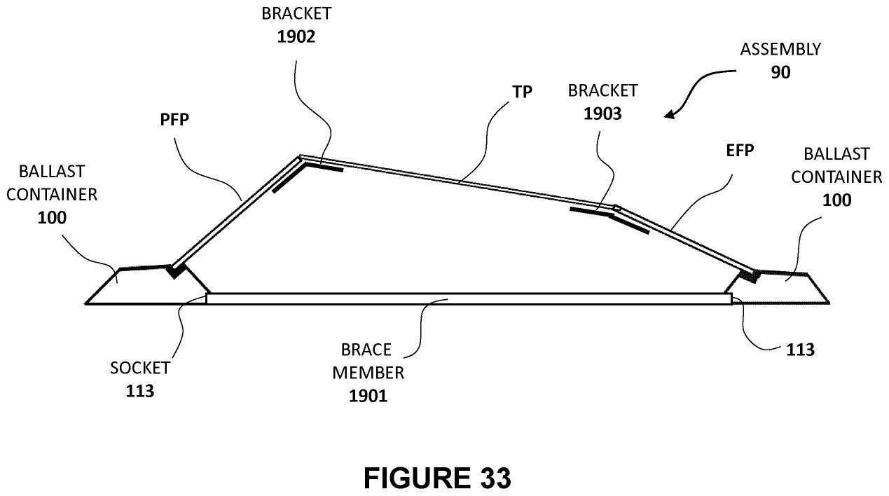

Another assembly embodiment 90 is illustrated in FIG. 33. This assembly embodiment 90 includes an arrangement of support components. The inventors have recognized that with the general arrangement shown in FIG. 5 which uses ballast container embodiment 100 may be provided with a base bracing member 1901 connected to lower sockets 113 of the ballast containers 100 to maintain proper spacing between the ballast containers 100, thereby permitting a simpler arrangement of supports in the form of brackets 1902 and 1903. These brackets may be used as a mechanism to connect adjacent panels to each other. FIG. 33 indicates that the PFP is connected to the TP and the TP is connected to the EFP. As long as the brace member 1901 connects the two ballast containers 100, the proper bracket angles will be maintained and sufficient structural support is provided for the assembly 90. This arrangement uses less support material and provides free space below the panels, which may be used for other purposes such as storage of miscellaneous equipment.

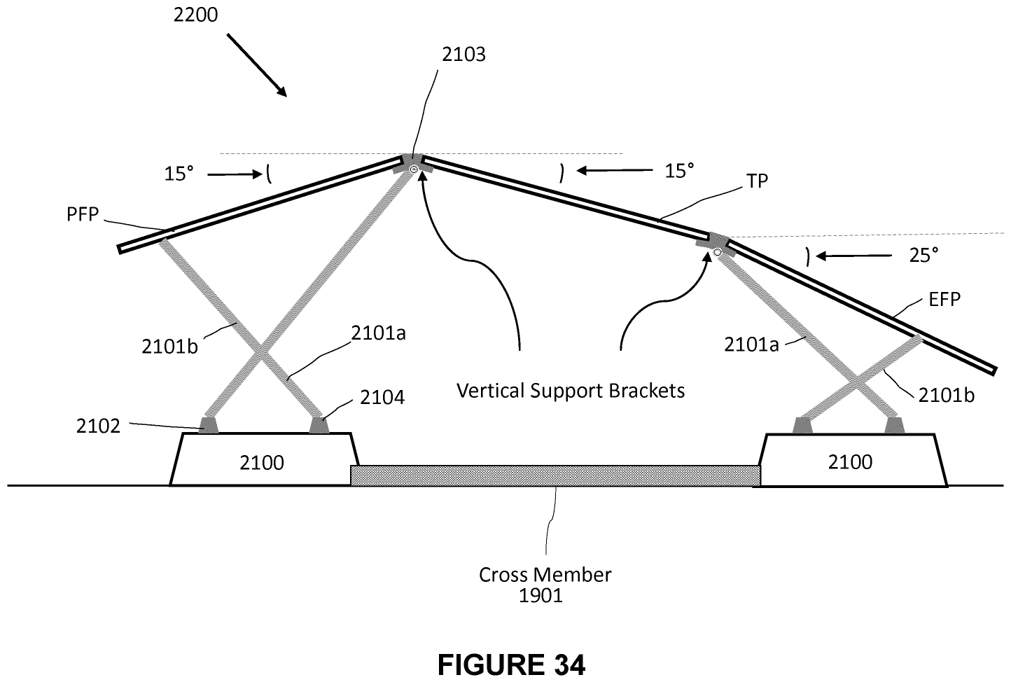

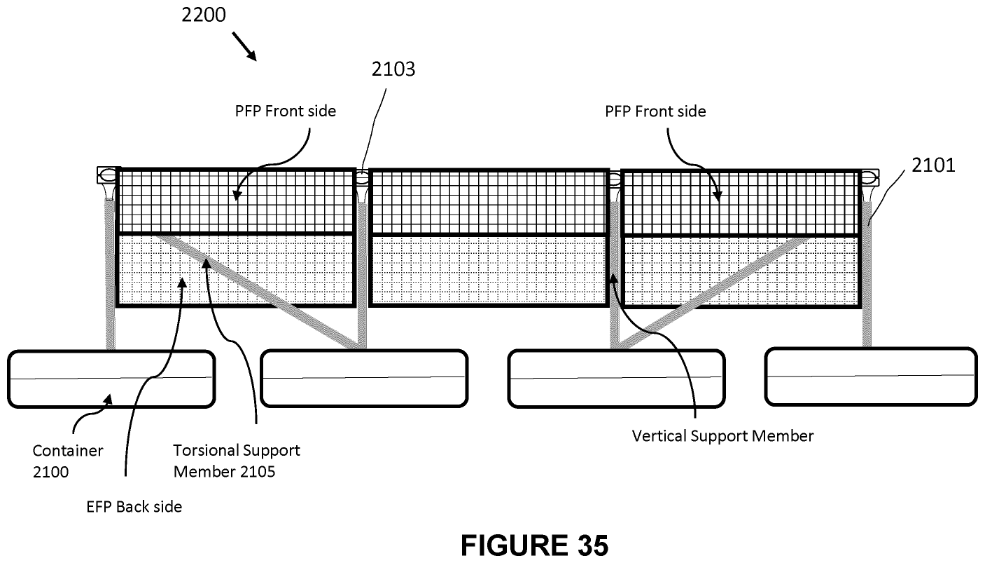

A further assembly embodiment 2200 is illustrated in FIGS. 34 and 35. In this assembly embodiment 2200, ballast containers 2100 provide support to, but are not directly connected to, panels PFP, TP and EFP. Instead, connection between ballast containers 2100 and panels PFP, TP and EFP are provided by support structures 2101. By including structural support structures 2101, panels PFP, TP and EFP are higher off the ground, providing additional space for human access underneath the panels for servicing and maintenance, while also providing space for movement of animals under the panels for various activities including grazing and/or for providing shade. In this embodiment, solar panels PFP, TP and EFP are elevated above the ground by members 2101 (including pairs 2101a and 2101b) that, in one example, are crossed with one another. The ends of each member may be pivotally connected to example brackets 2102, 2104 and 2103. Brackets 2102 and 2014 are illustrated as being fixed to ballast container 2100 where as bracket 2103 is illustrated as adapted for supporting solar panels PFP and TP at an angle with respect to one another.

Bracket 2103 may have a fixed angle between panels (e.g. PFP and TP) but may also be adjustable and/or enable a degree of movement or flexure between each panel.

A degree of movement/flexure can be beneficial to allow some movement for various reasons including potential some frost heave and/or to absorb wind energy through the support system.

Other arrangements and mechanisms for connecting supports and cross members to alternative embodiments of ballast containers are possible and are within the scope of the claims.

### Photovoltaic Frame With Access Port

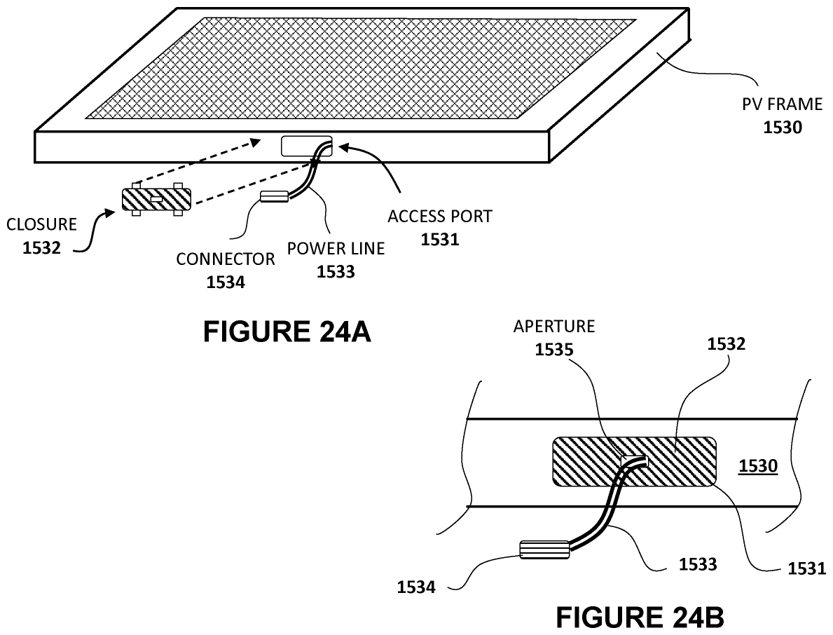

Turning now to FIGS. 24A and 24B, there is shown an embodiment of a photovoltaic panel formed using a frame 1530 which is provided with an access port 1531 so that electrical transmission wiring can be housed therein and removed to make connections between adjacent photovoltaic panels in either parallel wiring or series wiring arrangements. Photovoltaic frames incorporating an access port such as access port 1531 are expected to be marketed using the designation “PORE” to indicate a functional access port. Series wiring and parallel wiring both have advantages and disadvantages. Therefore, modification of a photovoltaic frame as described herein will provide flexibility in construction of photovoltaic assemblies. Parallel connections are mostly utilized in smaller, more basic systems. Connecting panels in parallel will increase current while voltage remains constant. The downside to parallel wiring systems is that high currents travelling over long distances require very thick wires. In addition, parallel wiring systems require extra equipment such as branch connectors and combiner boxes. As an alternative to parallel wiring, connection of photovoltaic panels in series will increase the voltage level while retaining constant current which simplifies transfer over long distances. The disadvantage to series wiring in photovoltaic installation is shading problems. When panels are wired in series, they all in a sense depend on each other. If one panel is shaded, it will affect the whole string. This does not occur in a parallel connection. Therefore, if a photovoltaic assembly can be constructed with minimal shading possibilities, series wiring may be advantageous.

FIG. 24A indicates that the photovoltaic frame 1530 with the access port 1531 permits a power line 1533 to extend therethrough. In this particular embodiment, the access port 1531 is provided with a closure 1532 with an aperture 1535 permitting the power line 1533 to extend therethrough as indicated in FIG. 24B. The power line 1533 is provided with a connector 1534 to facilitate making connections between panels.

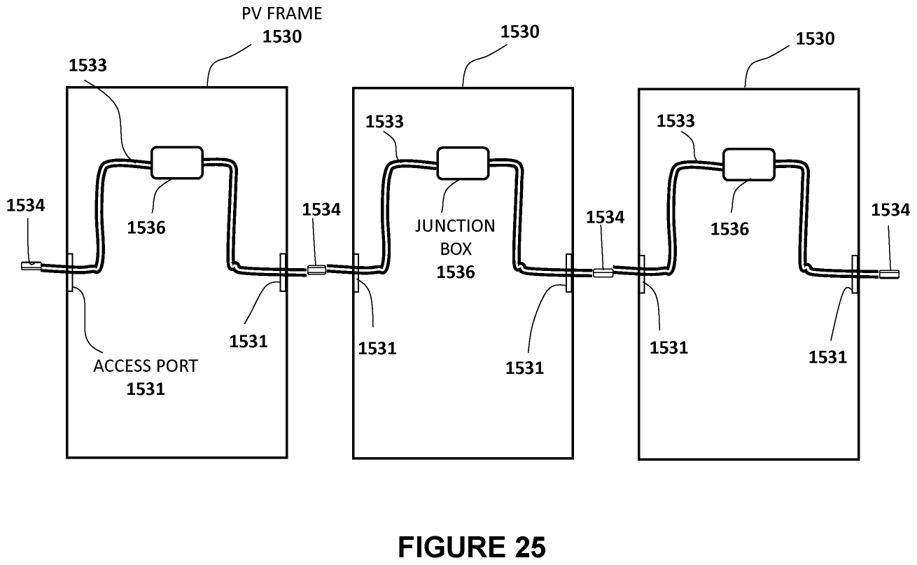

FIG. 25 illustrates series wiring across three photovoltaic frames 1530, each of which has a junction box 1536. The connectors 1534 are used to connect the power lines 1533 extending from adjacent photovoltaic frame 1530 via the access ports 1531.

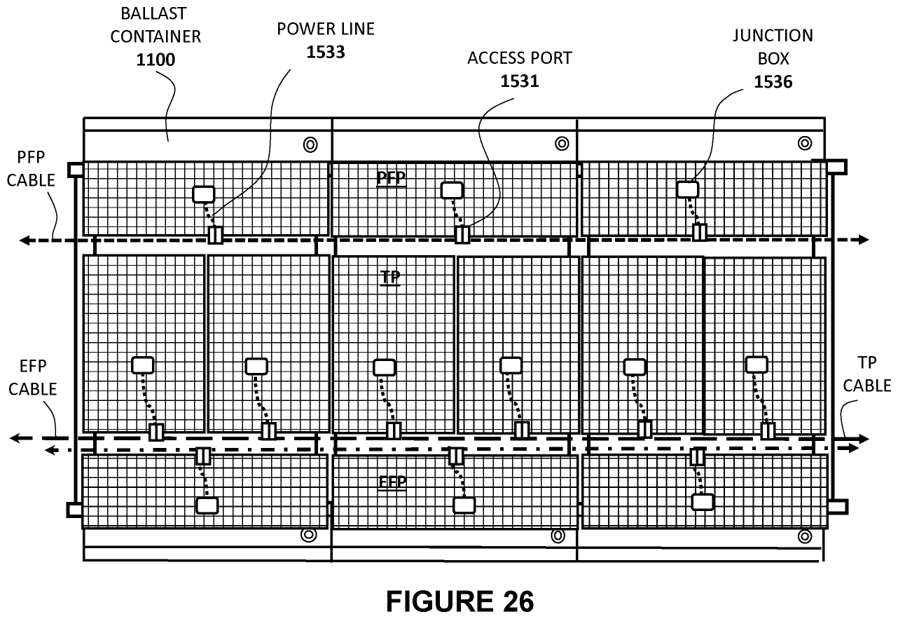

FIG. 26 is a top view of a photovoltaic assembly including equatorial facing panels EFP top panels TP and polar facing panels PFP arranged with parallel wiring. All panels include access ports 1531 to permit power lines 1533 extending from junction boxes 1536 to join corresponding PFP, EFP and TP cables extending longitudinally across the photovoltaic assembly.

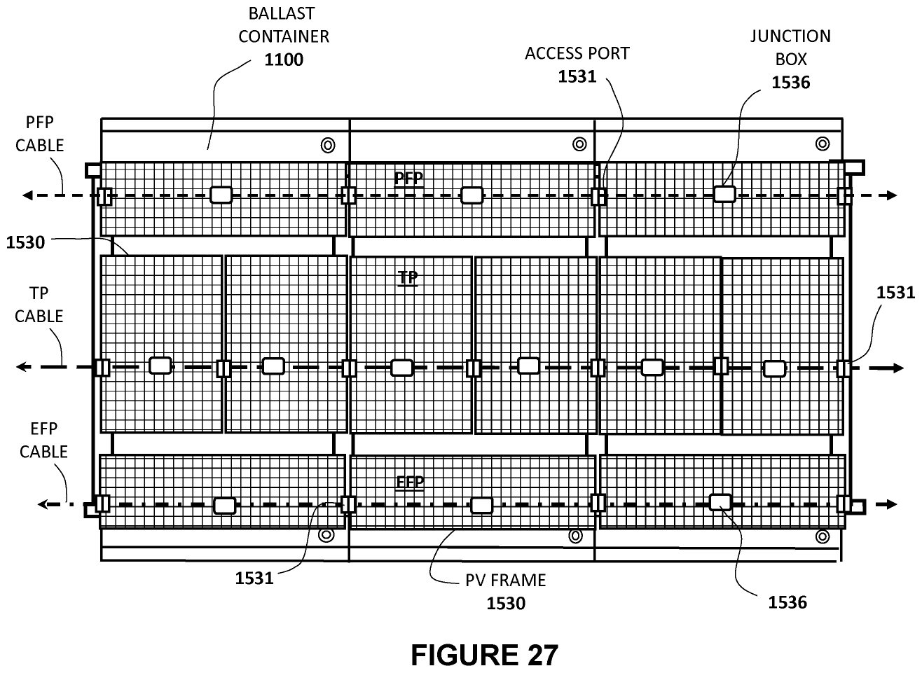

FIG. 27 is a top view of another photovoltaic assembly with the same general arrangement of panels illustrated in FIG. 26, having alternative placement of access ports 1531 to provide channels for series wiring. It is seen that in the three different alignments of panels PFP, TP and EFP, the series wiring extends across the panels longitudinally with respect to the assembly. It is generally advantageous to access ports 1531 opposed to each other within each photovoltaic frame 1530 as shown. In alternative embodiments, access ports 1531 may be provided on each side of the photovoltaic frame 1530 (not shown).

In photovoltaic assemblies such as the embodiments shown in FIGS. 25 to 27, it is advantageous to provide at least about 2 inches (about 5.1 cm) of space between the photovoltaic frames 1530 to facilitate making connections during assembly and/or for maintenance access.

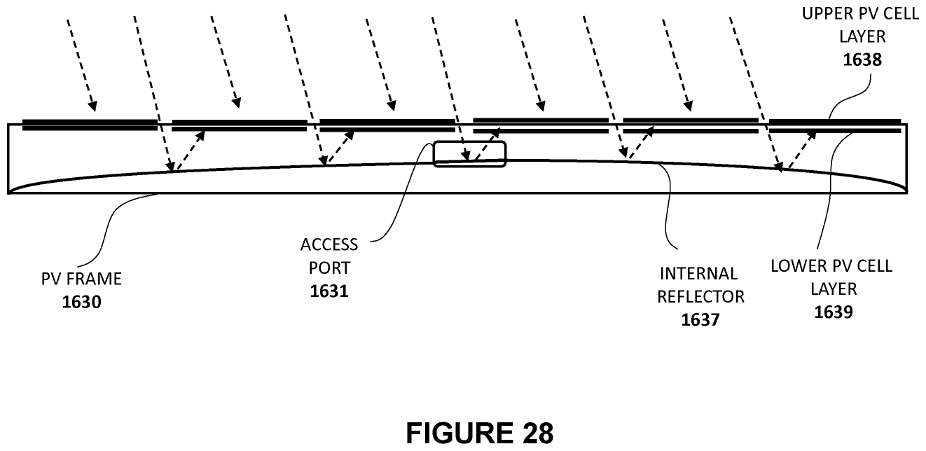

The provision of a photovoltaic frame such as frame 1530 provides an opportunity to use the space therein for other functional features. Turning now to FIG. 28, there is shown a side elevation view of another embodiment of a photovoltaic frame 1630 which has an access port 1631 and which includes an upper photovoltaic cell layer 1638 and a lower photovoltaic cell layer 1639 in a bifacial arrangement similar to the bifacial arrangements described hereinabove. This photovoltaic frame 1630 includes an internal reflector 1637, which is configured to receive irradiated light passing between the upper photovoltaic cell layers and reflect the light upward to be received by the lower photovoltaic cell layer. This arrangement improves harvesting of light energy directed against the photovoltaic frame 1630

### Mounting of Additional Functional Components to a Ballast Container

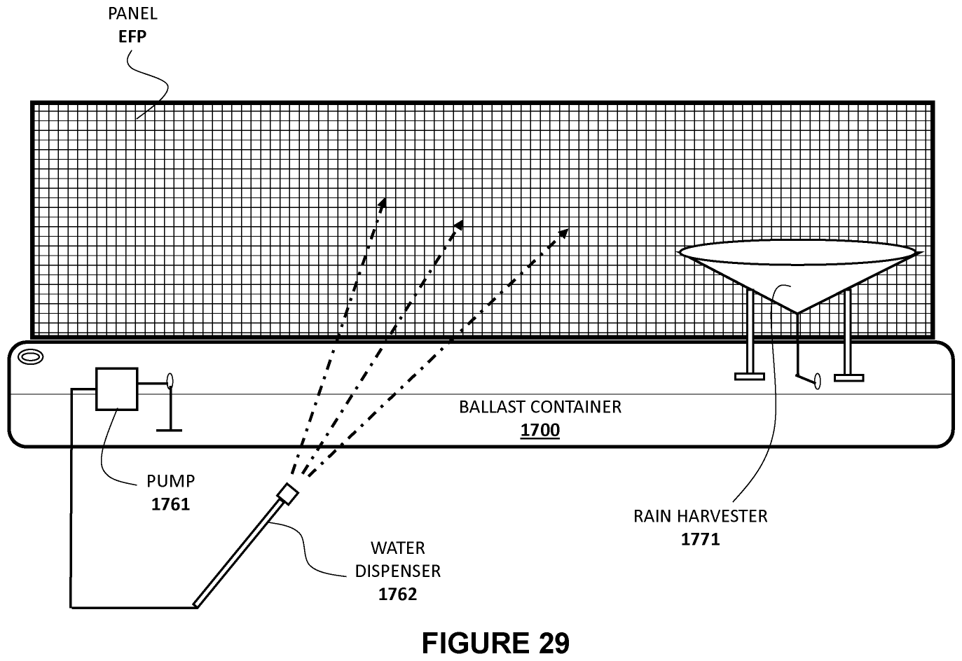

In keeping with the recognition that embodiments of ballast containers can provide a substrate for mounting or housing of functional components, FIG. 29 illustrates a side elevation view of an assembly based on another embodiment of a ballast container 1700, which includes a mounted water pump 1761 which is arranged to pump ballast water out of the ballast container 1700. The pumped water is conveyed to a water dispenser 1762, where it can be used to wash components of the photovoltaic assembly or for other maintenance functions such as cooling of certain components, if required.

This particular ballast container embodiment 1770 also supports a rain harvesting vessel 1771 for collecting rainwater and conveying it into the ballast container 1700 to replenish ballast water used for cleaning or maintenance.

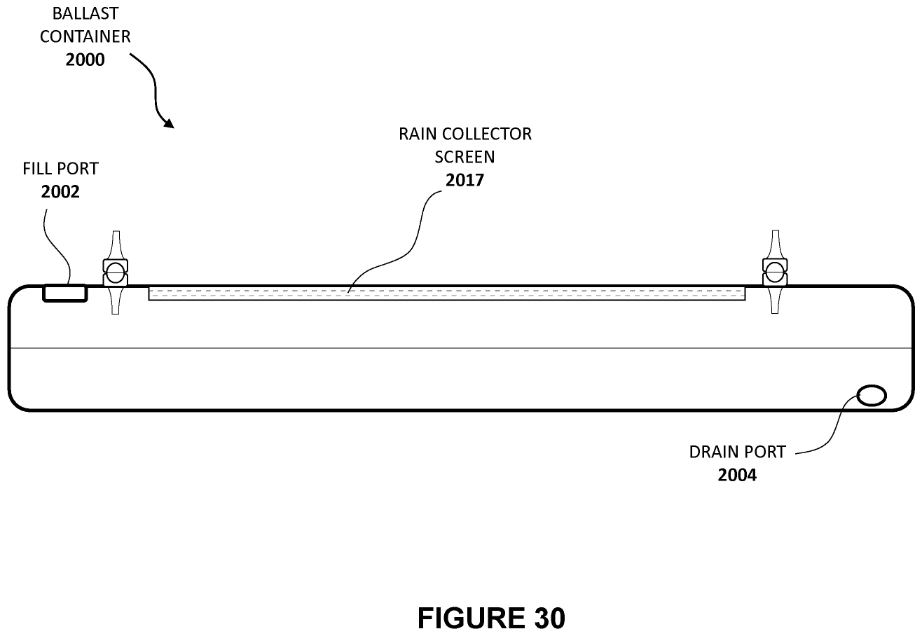

Another rain harvesting arrangement is shown in FIG. 30 which illustrates another ballast container embodiment 2000. This embodiment 2000 includes an upper fill port 2002, a lower drain port 2004 and an upper screen 2017 covering a wide opening in the upper surface of the ballast container 2000. The wide opening permits precipitation to drop into the interior volume of the ballast container 2000 where it can be used to replenish ballast water which has been used for cleaning or maintenance. The screen 2017 has advantages over the vessel 1771 of FIG. 29 in providing a more streamlined structure with greater collection surface area.

The foregoing description of various embodiments of ballast containers indicate that they can provide highly useful substrates for various functional components of photovoltaic assemblies, ranging in function from enhancement of solar energy collection to housing of sensitive components such as wiring and cables.

### Equivalents and Scope

Other than described herein, or unless otherwise expressly specified, all of the numerical ranges, amounts, values and percentages, such as those for amounts of materials, elemental contents, times and current rate, ratios of amounts, and others, in the following portion of the specification and attached claims may be read as if prefaced by the word “about” even though the term “about” may not expressly appear with the value, amount, or range. Accordingly, unless indicated to the contrary, the numerical parameters set forth in the following specification and attached claims are approximations that may vary depending upon the desired properties sought to be obtained. At the very least, and not as an attempt to limit the application of the doctrine of equivalents to the scope of the claims, each numerical parameter should at least be construed in light of the number of reported significant digits and by applying ordinary rounding techniques.

Any patent, publication, internet site, or other disclosure material, in whole or in part, that is said to be incorporated by reference herein is incorporated herein only to the extent that the incorporated material does not conflict with existing definitions, statements, or other disclosure material set forth in this disclosure. As such, and to the extent necessary, the disclosure as explicitly set forth herein supersedes any conflicting material incorporated herein by reference. Any material, or portion thereof, that is said to be incorporated by reference herein, but which conflicts with existing definitions, statements, or other disclosure material set forth herein will only be incorporated to the extent that no conflict arises between that incorporated material and the existing disclosure material.

Unless otherwise defined, all technical and scientific terms used herein have the same meaning as commonly understood by one of ordinary skill in the art.

While the technology been particularly shown and described with references to embodiments thereof, it will be understood by those skilled in the art that various changes in form and details may be made therein without departing from the scope of the technology encompassed by the appended claims.

In the claims, articles such as “a,” “an,” and “the” may mean one or more than one unless indicated to the contrary or otherwise evident from the context. Claims or descriptions that include “or” between one or more members of a group are considered satisfied if one, more than one, or all of the group members are present in, employed in, or otherwise relevant to a given product or process unless indicated to the contrary or otherwise evident from the context.

It is also noted that the term “comprising” is intended to be open and permits but does not require the inclusion of additional elements or steps. When the term “comprising” is used herein, the term “consisting of” is thus also encompassed and disclosed. Where ranges are given, endpoints are included. Furthermore, it is to be understood that unless otherwise indicated or otherwise evident from the context and understanding of one of ordinary skill in the art, values that are expressed as ranges can assume any specific value or subrange within the stated ranges in different embodiments of the technology, to the tenth of the unit of the lower limit of the range, unless the context clearly dictates otherwise. Where the term “about” is used, it is understood to reflect +/−10% of the recited value. In addition, it is to be understood that any particular embodiment of the present technology that falls within the prior art may be explicitly excluded from any one or more of the claims. Since such embodiments are deemed to be known to one of ordinary skill in the art, they may be excluded even if the exclusion is not set forth explicitly herein.

### REFERENCES

1. National Renewable Energy Laboratory Report NREL/TP-6A20-56290, 2013.
2. US Energy Information Administration Report. Most Utility-Scale Fixed-Tilt Photovoltaic Systems are Tilted 20 Degrees-30 Degrees, 2008.
3. Barkaszi, P. E. and O'Brien, C., Wind Load Calculations for PV Arrays, America Board for Codes and Standards, 2010.
4. Thurston, C. Ensuring Your Array Doesn't Get Caught in the Wind, Renewable Energy World, 2015, Volume 18.
5. Stantec Report, Project No. 193706562, Decommissioning Plan Western Mustang LLC, Pierce County, Wisconsin, 2019.
6. Photovoltaic Roadmap (ITRPV): Eleventh Edition Online, 2020, https://itrpv.vdma.org/7.
7. Silfab St Lawrence Project, 2019, https://silfab.com/the-bifacial-advantage/8.
8. Russell, C. R. et al., The Influence of Spectral Albedo ion Bifacial Cells: A Theoretical and Experimental Study, IEEE Journal of Photovoltaics, 2017.
9. U.S. Provisional Patent Application Ser. No. 63/039,775.
10. Mills, S. ESG Focus: Plastic Recycling Disruption Part 2, FNArena, April, 2020.

Each of the references in this list is incorporated herein by reference in entirety.

1. An anchoring system for anchoring at least one solar panel against the ground, the anchoring system comprising:
a container configured to hold ballast within the container, the container having a lower surface for engagement with the ground and an upper surface having a solar panel connection system for attaching at least one solar panel to the container at an angle with respect to the ground.

2. The anchoring system as in claim 1 where the container is a hollow plastic container configured to hold water and/or a particulate as ballast.

3. The anchoring system as in claim 2 where the container includes at least one fill port for filling the container with the ballast material; and at least one drain port for draining the ballast material from the container.

4. (canceled)

5. The anchoring system of claim 3 wherein the container has a container length, container width and container height and where the solar panel connection system is selected from a group consisting of: (a) a groove formed in the upper surface of the container extending along the container length and where the groove is configured to receive and secure an edge of at least one solar panel to the container, and (b) at least one bracket configured to the upper surface and each at least one bracket is configured to connect an edge of the at least one solar panel to the at least one bracket.

6. (canceled)

7. The anchoring system of claim 5 where the solar panel connection system is configured to enable adjustment of a solar panel angle with respect to the ground when a solar panel is connected to the container.

8. The anchoring system of claim 7 wherein the container has a base surface and an upper surface and where the base surface is wider than the upper surface such that the container defines a substantially trapezoidal cross-section.

9. The anchoring system as in claim 8 wherein the base surface includes an upwardly-extending recess along the container length for receiving a lifting device within the recess.

10. The anchoring system of claim 9 wherein the container further includes a cable groove extending along the container length configured to support at least one solar panel cable.

11. The anchoring system of claim 10 wherein the container further includes a reflector support configured to support a reflector on the upper surface of the container.

12. The anchoring system of claim 11 wherein the container is configured to connect at least one solar panel support bracket to the container and where the anchoring system further comprises a solar panel support bracket having a bracket upper surface configured to support a lower surface of a first solar panel a first angle with respect to the ground.

13. The anchoring system as in claim 12 wherein the solar panel support bracket further comprises an upper corner extension extending laterally from the solar panel support bracket, the upper corner extension configured to support a second panel at a second angle with respect to the ground.

14. (canceled)

15. The anchoring system of claim 13 wherein the container is configured with at least one recessed slot on a side surface of the container and wherein the solar panel support bracket has an edge configured to lock with the recessed slot.

16. The anchoring system of claim 15 wherein the container is configured with an end connection system configured to connect to a corresponding end connection system of a second container enabling interconnection of multiple containers longitudinally.

17. The anchoring system of claim 16 wherein the container includes a cross-member connection system configured to connect a cross-member between two or more corresponding containers laterally separated from one another, and the cross-member is further configured to provide a fixed separation between adjacent rows of containers.

18. (canceled)

19. (canceled)

20. The anchoring system as in claim 1 further comprising at least one panel lift member configured to connect a container with a solar panel and to provide vertical separation between a solar panel and a container.

21. The anchoring system as in claim 20 further comprising at least one torsion control member configured to connect a container with a solar panel and to provide torsional stability to an elevated solar panel.

22. A kit comprising:
at least two hollow containers configured to hold ballast material within the container, each container having a lower surface for engagement with the ground and an upper surface having a solar panel connection system for attaching at least one solar panel to each container at an angle with respect to the ground.

23. The kit of claim 22, further comprising at least two solar panels.

24. The kit of claim 23 further comprising at least one panel support bracket having a bracket upper surface configured to support a lower surface of a first solar panel at a first angle with respect to the ground.

25. The kit of claim 24 further comprising at least one cross member configured to connect two containers together with a fixed separation between the two containers and at least one solar panel connector configured to connect two solar panels together.

26. (canceled)

27. The kit of claim 25 further comprising further comprising a reflector and wherein at least one container is configured to the reflector to the at least one container at an angle to the ground.

28. A solar panel assembly comprising:
at least two hollow containers configured to hold ballast material within the container, each container having a lower surface for engagement with the ground and an upper surface having a solar panel connection system for attaching at least one solar panel to each container at an angle with respect to the ground;
a first solar panel connected to a first container;
a second solar panel connected to a second container;
wherein the first and second solar panels are connected together to define a solar panel assembly wherein each solar panel is angled with respect to the ground.

29. The solar panel assembly of claim 28 further comprising at least one panel support bracket connected to the first container and having a bracket upper surface configured to support a lower surface of the first solar panel at a first angle with respect to the ground.

30. The solar panel assembly of claim 29 further comprising at least one cross member connected to the first container and second container and at least one solar panel connector commonly connected to the first and second solar panels.

31. (canceled)

32. The solar panel assembly of claim 30 further comprising a reflector connected to the first container at an angle to the ground.

33. The solar panel assembly of claim 32, further comprising a third solar panel and wherein the first and second solar panels are connected to one another by the third solar panel between the first and second solar panels.

34. The solar panel assembly of claim 33, wherein each container is filled with water and the solar panel assembly further comprises a pump and dispenser in fluid communication with container water.

35. The solar panel assembly of claim 34, further comprising a rain harvesting vessel or screen configured to convey captured precipitation into the first container.
